(19) United States
(12) Patent Application Publication
(10) Pub. No.: US 2026/0044082 A1
(43) Pub. Date: Feb. 12, 2026

(54) RESIST UNDERLAYER FILM-FORMING COMPOSITION

(71) Applicant: NISSAN CHEMICAL CORPORATION, Tokyo (JP)

(72) Inventors: Kosuke IGATA, Toyama-shi (JP); Hiroto OGATA, Toyama-shi (JP); Tomotada HIROHARA, Toyama-shi (JP)

(73) Assignee: NISSAN CHEMICAL CORPORATION, Tokyo (JP)

(21) Appl. No.: 19/099,855

(22) PCT Filed: Aug. 2, 2023
(86) PCT No.: PCT/JP2023/028224

§ 371 Date: Jan. 30, 2025

(30) Foreign Application Priority Data
Aug. 2, 2022 (JP) 2022-123364

(51) Int. Cl. G03F 7/11; C08F 8/14; C08F 8/30; C08F 120/32; C08F 220/32; C09D 133/06; H01L 21/027; H01L 21/3065; H01L 21/308

(52) U.S. Cl. CPC G03F 7/11; C09D 133/068; H01L 21/0275; C08F 8/14; C08F 8/30; C08F 120/32; C08F 220/325; H01L 21/3065; H01L 21/3081

(57) ABSTRACT

A resist underlayer film-forming composition includes: a polymer; and a solvent, in which the polymer has, in a side chain, one or two or more polymerizable multiple bonds selected from the group consisting of a carbon-carbon double bond, a carbon-carbon triple bond, a carbon-nitrogen double bond, and a carbon-nitrogen triple bond.

### TECHNICAL FIELD

The present invention relates to a resist underlayer film-forming composition, a resist underlayer film, a laminate, a method for producing a semiconductor element, and a method for forming a pattern.

### BACKGROUND ART

In the related art, fine processing by lithography using resist compositions has been performed in the production of semiconductor devices. The fine processing is a processing method including: forming a photoresist composition thin film on a semiconductor substrate such as a silicon wafer; irradiating the thin film with active rays such as ultraviolet rays through a mask pattern having a device pattern drawn thereon; developing the irradiated thin film; and etching the substrate with the resultant photoresist pattern serving as a protective film to form, on the surface of the substrate, fine irregularities corresponding to the photoresist pattern. In recent years, semiconductor devices have become more highly integrated, and in addition to typically used active rays: i-line (wavelength: 365 nm), KrF excimer laser (wavelength: 248 nm), and ArF excimer laser (wavelength: 193 nm), the practical use of EUV light (wavelength: 13.5 nm) or electron beam (EB) in the most advanced fine processing has been studied. The use of such active rays has caused a serious problem in terms of defects in resist pattern formation due to an influence from a semiconductor substrate or the like. Thus, in order to solve this problem, a method of providing a resist underlayer film between a resist and a semiconductor substrate has been widely studied.

Patent Literature 1 discloses an underlayer film-forming composition for lithography including a naphthalene ring having a halogen atom. Patent Literature 2 discloses a halogenated anti-reflective coating. Patent Literature 3 discloses a resist underlayer film-forming composition.

### CITATION LIST

### Patent Literature

Patent Literature 1: WO 2006/003850 A
Patent Literature 2: JP 2005-526270 A
Patent Literature 3: WO 2020/111068 A

### SUMMARY OF INVENTION

### Technical Problem

For example, a resist underlayer film is desirably characterized in that no intermixing with a resist film formed on an upper layer occurs (the resist film is insoluble in a resist solvent), and a fine resist pattern can be formed.

The present invention has been made in view of the above circumstances, and an object of the present invention is to provide a resist underlayer film-forming composition capable of forming a resist underlayer film on which a fine resist pattern can be formed, and a resist underlayer film formed, a laminate, a method for producing a semiconductor element, and a method for forming a pattern using the resist underlayer film-forming composition.

### Solution to Problem

As a result of intensive studies to solve the above problem, the present inventors have found that the above problem can be solved, thereby completing the present invention having the following gist.

That is, the present invention includes the following aspects.
[1] A resist underlayer film-forming composition including: a polymer (A); and a solvent, wherein the polymer (A) has, in a side chain, one or two or more polymerizable multiple bonds selected from the group consisting of a carbon-carbon double bond, a carbon-carbon triple bond, a carbon-nitrogen double bond, and a carbon-nitrogen triple bond.
[2] The resist underlayer film-forming composition according to [1], wherein in the polymer (A), the polymerizable multiple bond is bonded to a main chain of the polymer (A) via a linking group having a structure formed by reacting an epoxy group with a nucleophilic functional group.
[3] The resist underlayer film-forming composition according to [2], wherein the nucleophilic functional group is one or two or more selected from the group consisting of a carboxy group, a hydroxy group, an amino group, and a thiol group.
[4] The resist underlayer film-forming composition according to [1],
wherein in the polymer (A), the polymerizable multiple bond is bonded to a main chain of the polymer (A) via a linking group having a structure formed by reacting an isocyanate group with a nucleophilic functional group, and the nucleophilic functional group is one or two or more selected from the group consisting of a hydroxy group, an amino group, and a thiol group.
[5] The resist underlayer film-forming composition according to any one of [1] to [4], wherein the polymer (A) has a structural unit represented by the following Formula (1):

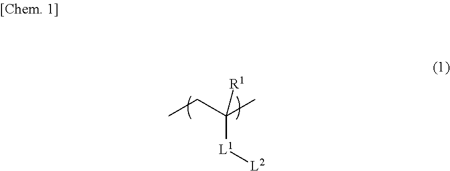

where in Formula (1), R¹ represents a hydrogen atom or an alkyl group having 1 to 10 carbon atoms, L¹ represents a single bond or a linking group, and L² represents a monovalent group having the polymerizable multiple bond.
[6] The resist underlayer film-forming composition according to [5], wherein L¹-L² in the structural unit represented by the Formula (1) has a structure represented by the following Formula (1a), (1b) or (1c):

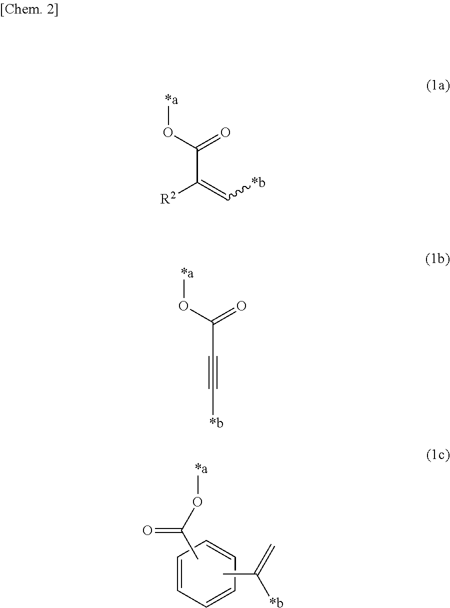

where in Formulae (1a) to (1c), R² represents a hydrogen atom or an alkyl group having 1 to 10 carbon atoms, *a and *b each represent a bonding hand, *a is a main chain side of the polymer (A), and *b is an end side of a side chain of the polymer (A).
[7] The resist underlayer film-forming composition according to any one of [1] to [6], further containing a crosslinking agent.
[8] A resist underlayer film which is a cured product of the resist underlayer film-forming composition described in any one of [1] to [7].
[9] A laminate including:
a semiconductor substrate; and
the resist underlayer film described in [7].
[10] A method for producing a semiconductor element, the method including the steps of:
forming a resist underlayer film on a semiconductor substrate using the resist underlayer film-forming composition described in any one of [1] to [7]; and
forming a resist film on the resist underlayer film.
[11] A method for forming a pattern, the method including the steps of:
forming a resist underlayer film on a semiconductor substrate using the resist underlayer film-forming composition described in any one of [1] to [7];
forming a resist film on the resist underlayer film;
irradiating the resist film with light or an electron beam, and then developing the resist film to form a resist pattern; and
etching the resist underlayer film using the resist pattern as a mask.

### Advantageous Effects of Invention

According to the present invention, it is an object to provide a resist underlayer film-forming composition capable of forming a resist underlayer film on which a fine resist pattern can be formed, and a resist underlayer film formed, a laminate, a method for producing a semiconductor element, and a method for forming a pattern using the resist underlayer film-forming composition.

### DESCRIPTION OF EMBODIMENTS

### (Resist Underlayer Film-Forming Composition)

The resist underlayer film-forming composition of the present invention contains a polymer (A) and a solvent.

### <Polymer (A)>

The polymer (A) has a polymerizable multiple bond in a side chain.

The polymerizable multiple bond is one or two or more polymerizable multiple bonds selected from the group consisting of a carbon-carbon double bond, a carbon-carbon triple bond, a carbon-nitrogen double bond, and a carbon-nitrogen triple bond.

The polymer (A) is an organic polymer.

The polymer (A) may be a homopolymer or a copolymer.

The polymer (A) has, for example, a (meth)acryloyl group, a vinylaryl group (e.g. a styryl group), a vinyloxy group, or an allyl group as a group having a polymerizable multiple bond in a side chain.

The polymer (A) is, for example, a polymer (A-1) formed by polymerizing a polymerizable unsaturated bond of a compound having a group having the polymerizable unsaturated bond. The polymer (A-1) may be a homopolymer or a copolymer.

Examples of the group having a polymerizable unsaturated bond include a (meth)acryloyl group, a vinylaryl group (e.g. a styryl group), a vinyloxy group, and an allyl group.

For example, in the polymer (A), the polymerizable multiple bond is bonded to a main chain of the polymer (A) via a linking group having a structure formed by reacting an epoxy group with a nucleophilic functional group.

Examples of the nucleophilic functional group include one or two or more selected from the group consisting of a carboxy group, a hydroxy group, an amino group, and a thiol group. The hydroxy group may be a phenolic hydroxy group, or need not be a phenolic hydroxy group.

When an epoxy group reacts with a carboxy group, the following reaction occurs to form the following structure (S1):

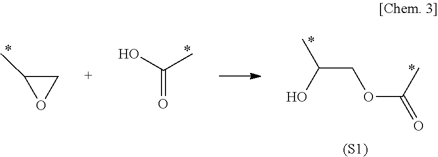

where * represents a bonding hand.

For example, in the polymer (A), the polymerizable multiple bond is bonded to a main chain of the polymer (A) via a linking group having a structure formed by reacting an isocyanate group with a nucleophilic functional group. In this case, examples of the nucleophilic functional group include one or two or more selected from the group consisting of a hydroxy group, an amino group, and a thiol group. The hydroxy group may be a phenolic hydroxy group, or need not be a phenolic hydroxy group.

The polymer (A) preferably has a structural unit represented by the following Formula (1):

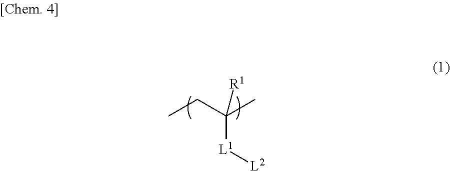

where in Formula (1), R¹ represents a hydrogen atom or an alkyl group having 1 to 10 carbon atoms, L¹ represents a single bond or a linking group, and L² represents a monovalent group having the polymerizable multiple bond.

Examples of the alkyl group having 1 to 10 carbon atoms include a methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1, 2-dimethyl-n-propyl group, 2, 2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2, 3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1, 2-dimethyl-n-butyl group, 1,3-dimethyl-n-butyl group, 2, 2-dimethyl-n-butyl group, 2,3-dimethyl-n-butyl group, 3, 3-dimethyl-n-butyl group, 1-ethyl-n-butyl group, 2-ethyl-n-butyl group, 1, 1, 2-trimethyl-n-propyl group, 1, 2, 2-trimethyl-n-propyl group, 1-ethyl-1 methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2, 2-dimethyl-cyclobutyl group, 2,3-dimethyl-cyclobutyl group, 2,4-dimethyl-cyclobutyl group, 3, 3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1, 2, 2-trimethyl-cyclopropyl group, 1, 2, 3-trimethyl-cyclopropyl group, 2, 2, 3-trimethyl-cyclopropyl group, 1-ethyl-2 methyl-cyclopropyl group, 2-ethyl-1-methyl-cyclopropyl group, 2-ethyl-2-methyl-cyclopropyl group, 2-ethyl-3-methyl-cyclopropyl group, n-heptyl group, cycloheptyl group, norbornyl group, n-octyl group, cyclooctyl group, n-nonyl group, isobornyl group, tricyclononyl group, n-decyl group, adamantyl group, and tricyclodecyl group. Among these groups, a methyl group is preferred.

When L¹ is a linking group, the number of carbon atoms of the linking group is not particularly limited. For example, the number of carbon atoms of the linking group is 1 to 10.

When L¹ is a linking group, examples of the linking group include a linking group having a structure formed by reacting an epoxy group with a nucleophilic functional group, and a linking group having a structure formed by reacting an isocyanate group with a nucleophilic functional group.

Examples of L¹ include the following linking groups (L1-1) to (L1-11):

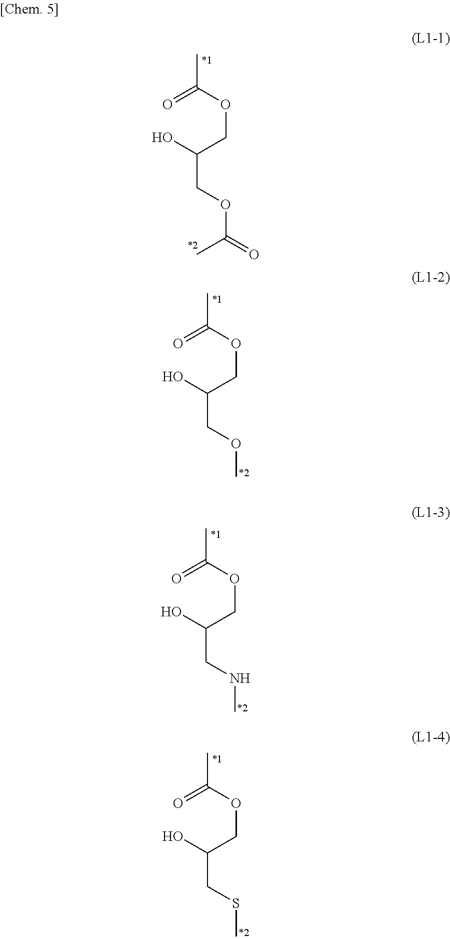

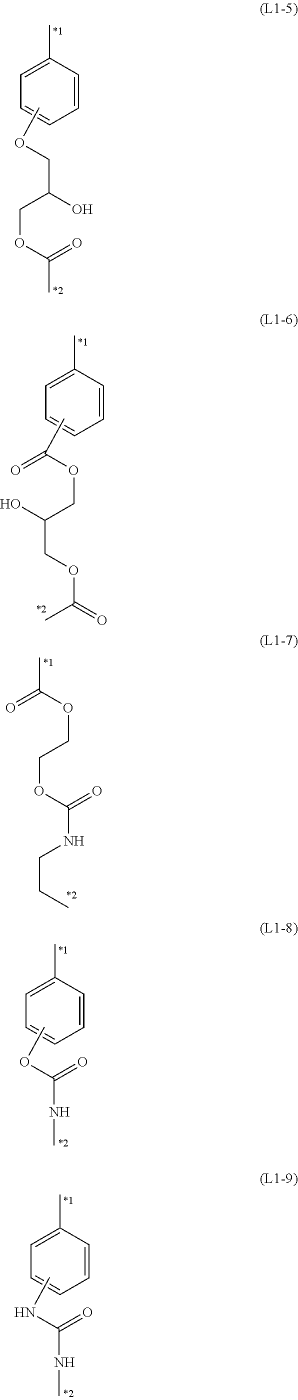

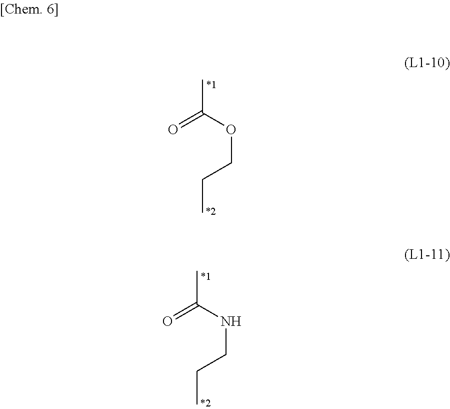

where *1 represents a bonding hand bonded to a carbon atom bonded to R¹ in Formula (1), and *2 represents a bonding hand bonded to L² in Formula (1).

L² is a monovalent group having a polymerizable multiple bond. The monovalent group may be a polymerizable multiple bond itself.

The number of carbon atoms of the monovalent group is not particularly limited, and may be, for example, 1 to 20 or 1 to 10.

Examples of L² include the following monovalent groups (L2-1) to (L2-81):

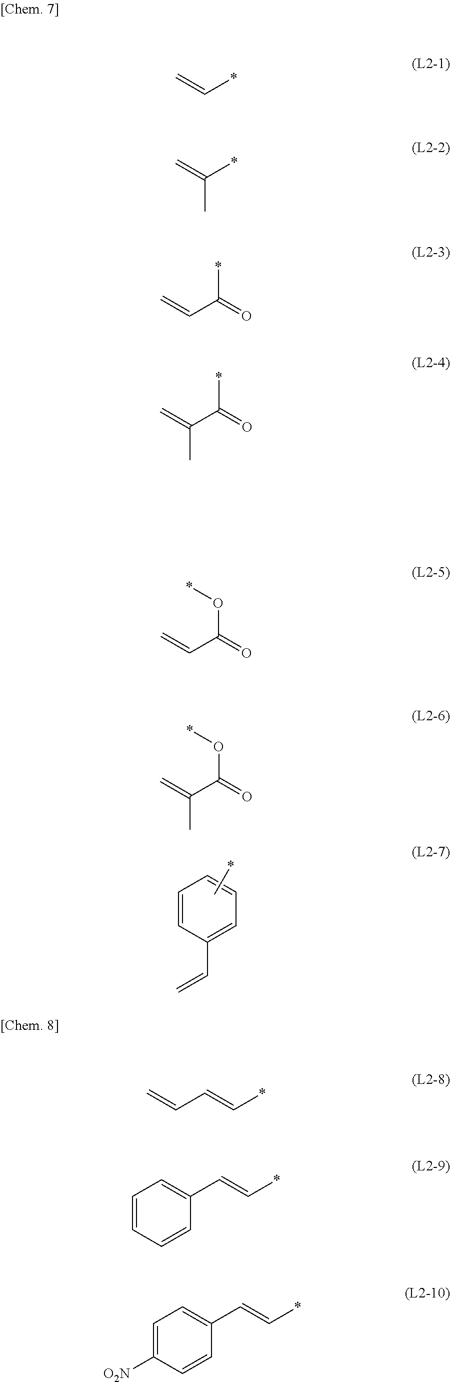

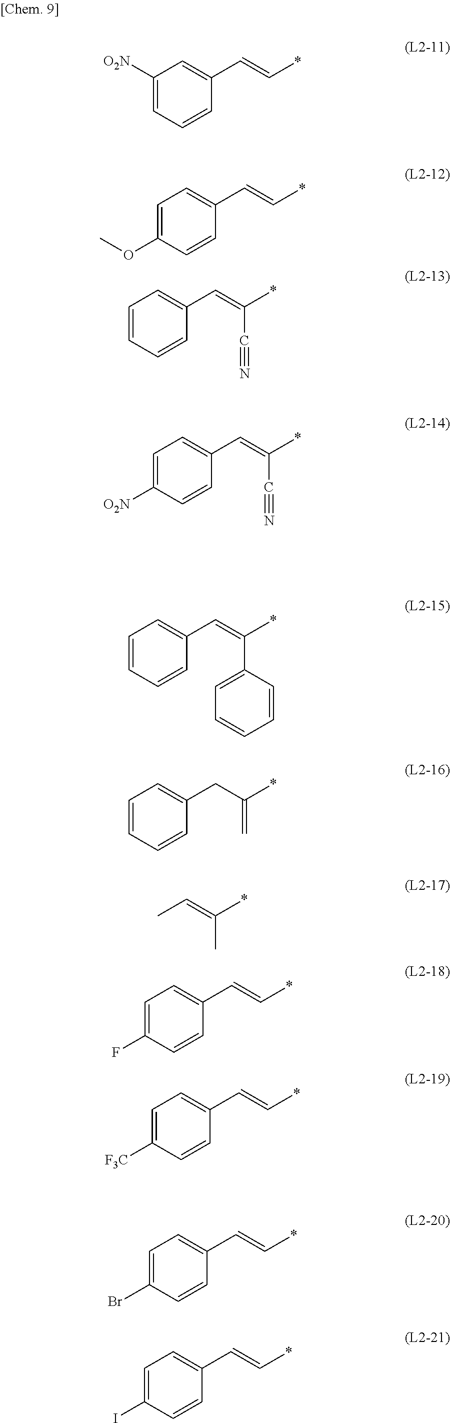

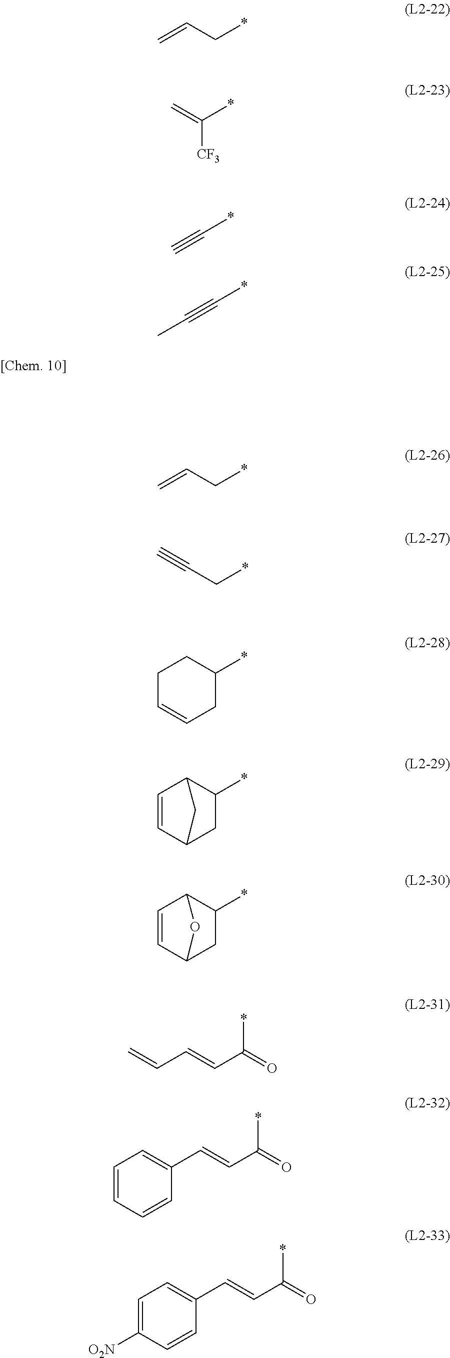

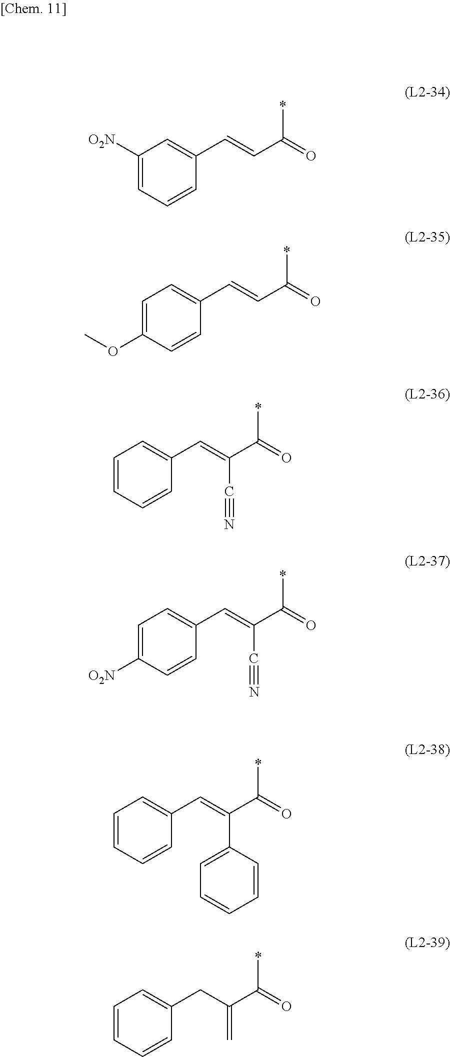 [SMILES: *C(=O)/C=C/c1cccc([N+](=O)[O-])c1 ; *C(=O)/C=C/c1ccc(OC)cc1 ; *C(=O)/C(C#N)=C/c1ccccc1 ; *C(=O)/C(C#N)=C/c1ccc([N+](=O)[O-])cc1 ; *C(=O)/C(=C/c1ccccc1)c1ccccc1 ; *C(=O)C(=C)Cc1ccccc1]

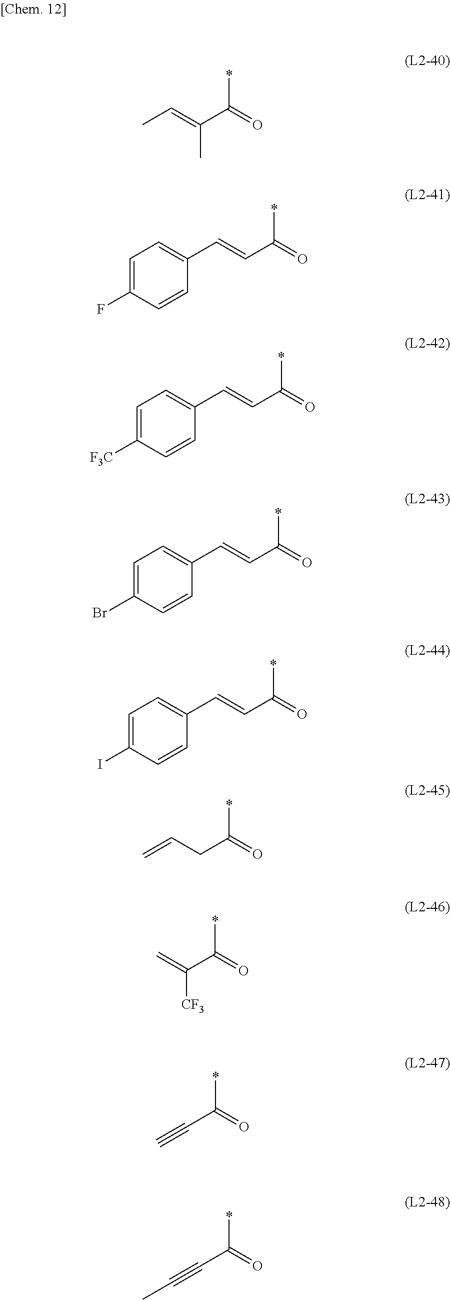

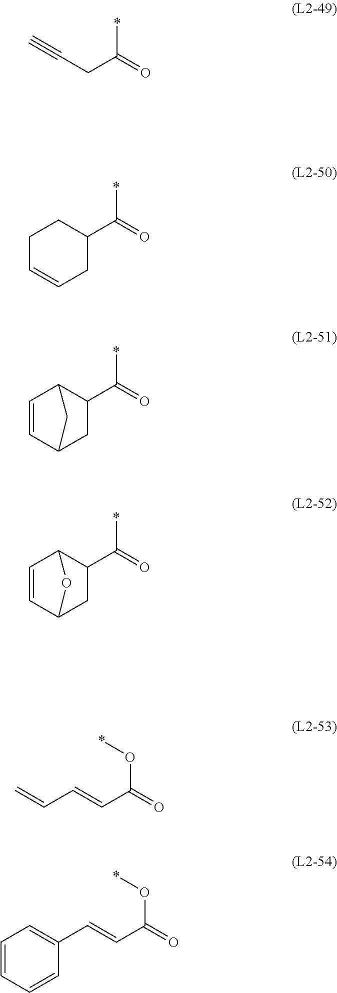

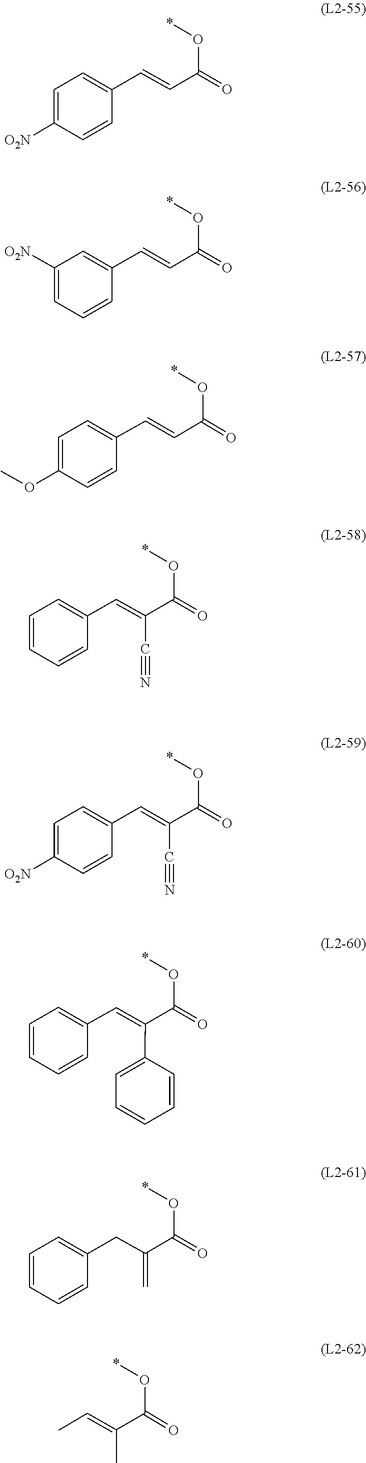

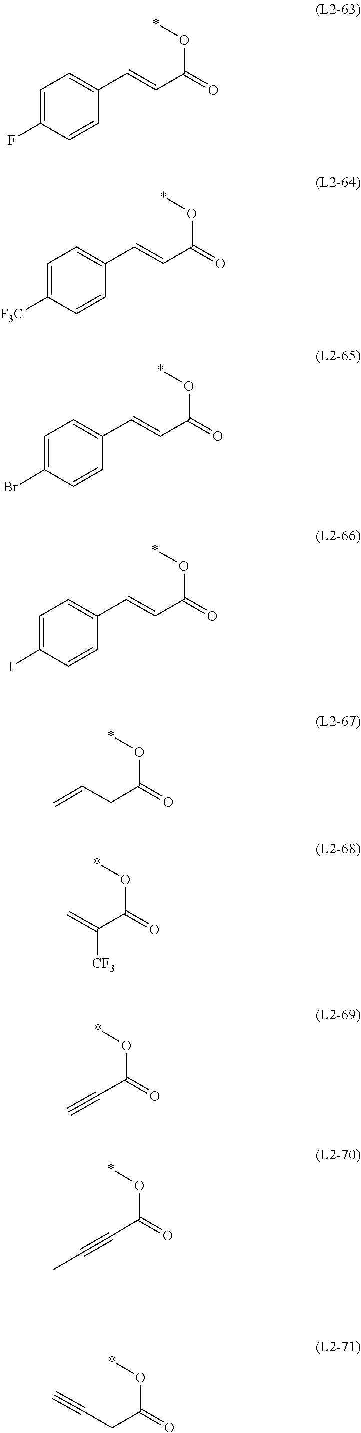

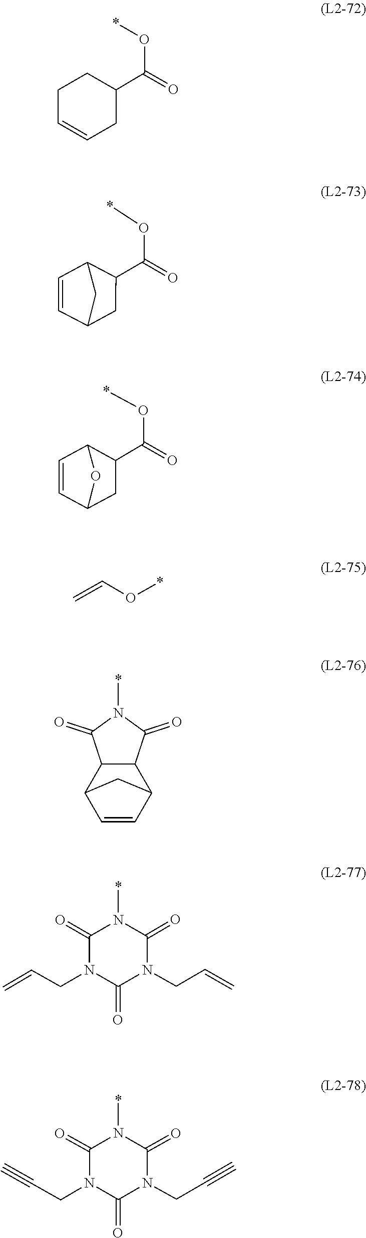

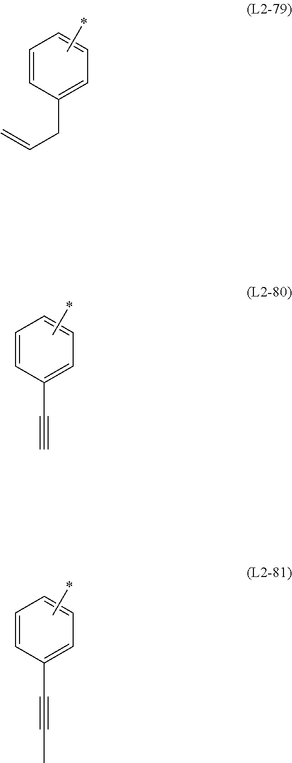

where * represents a bonding hand.

Examples of the combination of the linking groups (L1-1) to (L1-9) and the monovalent groups (L2-1) to (L2-7) include the following combinations:
Combination of (L1-1) and (L2-1);
Combination of (L1-1) and (L2-2);
Combination of (L1-1) and (L2-7);
Combination of (L1-2) and (L2-3);
Combination of (L1-2) and (L2-4);
Combination of (L1-2) and (L2-7);
Combination of (L1-3) and (L2-3);
Combination of (L1-3) and (L2-4);
Combination of (L1-4) and (L2-7);
Combination of (L1-5) and (L2-1);
Combination of (L1-5) and (L2-2);
Combination of (L1-6) and (L2-1);
Combination of (L1-6) and (L2-2);
Combination of (L1-7) and (L2-5);
Combination of (L1-7) and (L2-6);
Combination of (L1-8) and (L2-7); and
Combination of (L1-9) and (L2-7).

The combination of (L1-1) and (L2-1) is synonymous with the combination of (L1-2) and (L2-3). The combination of (L1-1) and (L2-2) is synonymous with the combination of (L1-2) and (L2-4).

In addition, L¹-L² in the structural unit represented by Formula (1) preferably has a structure represented by the following Formula (1a), (1b) or (1c):

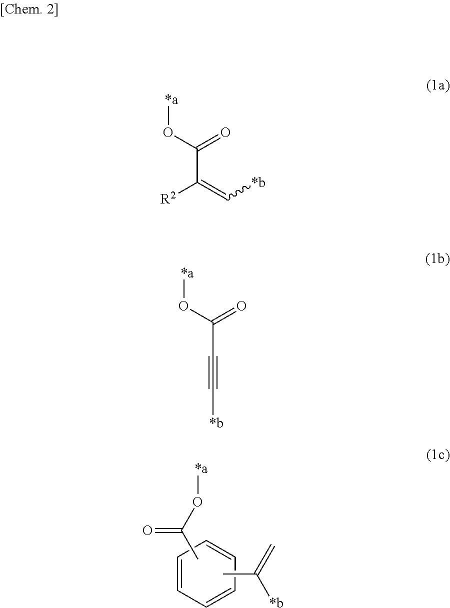

where in Formulae (1a) to (1c), R² represents a hydrogen atom or an alkyl group having 1 to 10 carbon atoms, *a and *b each represent a bonding hand, *a is a main chain side of the polymer (A), and *b is an end side of a side chain of the polymer (A).

Note that *b may be a bonding hand with a hydrogen atom.

Examples of the structural unit represented by Formula (1) include the following structural units:

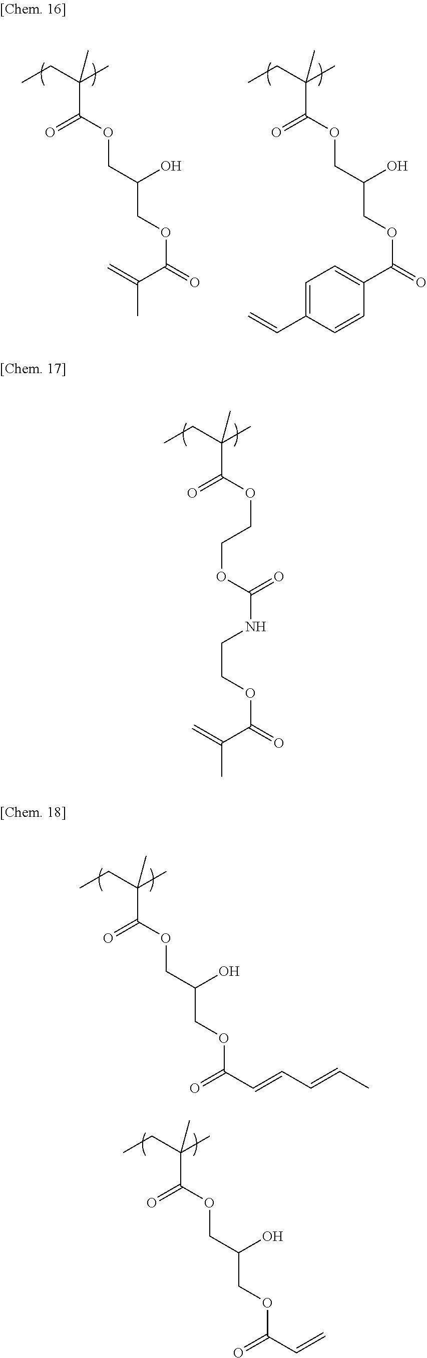

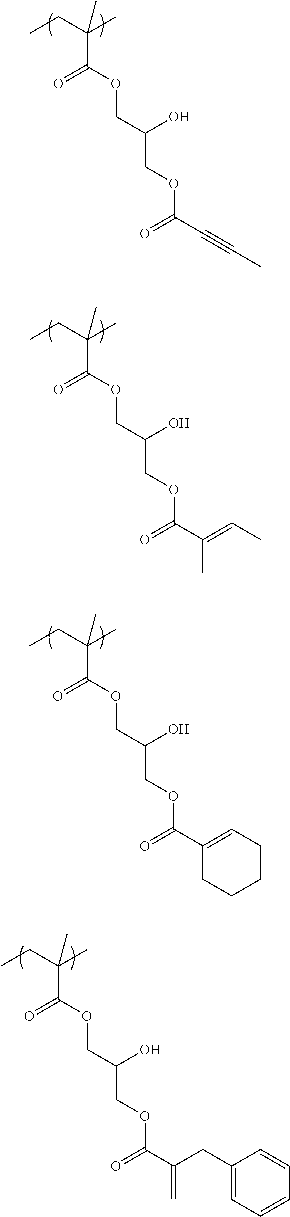

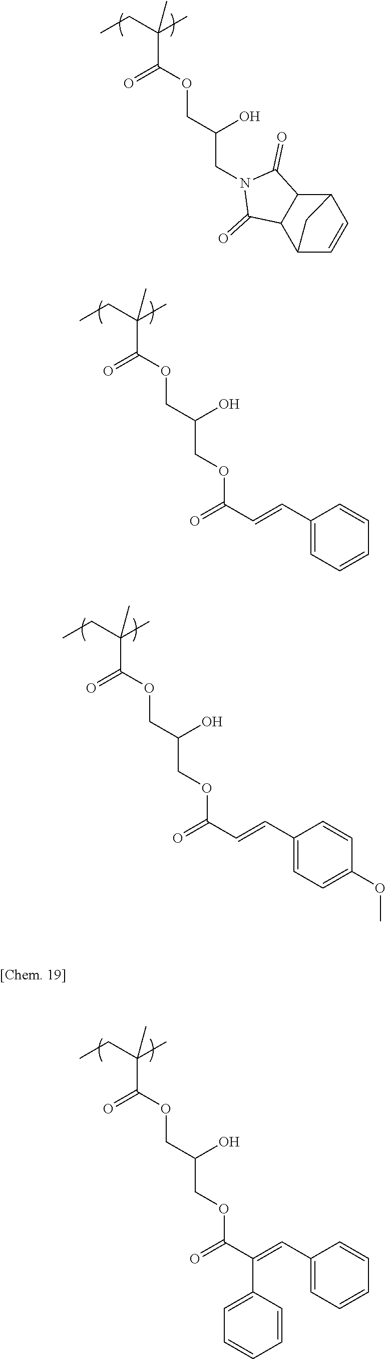

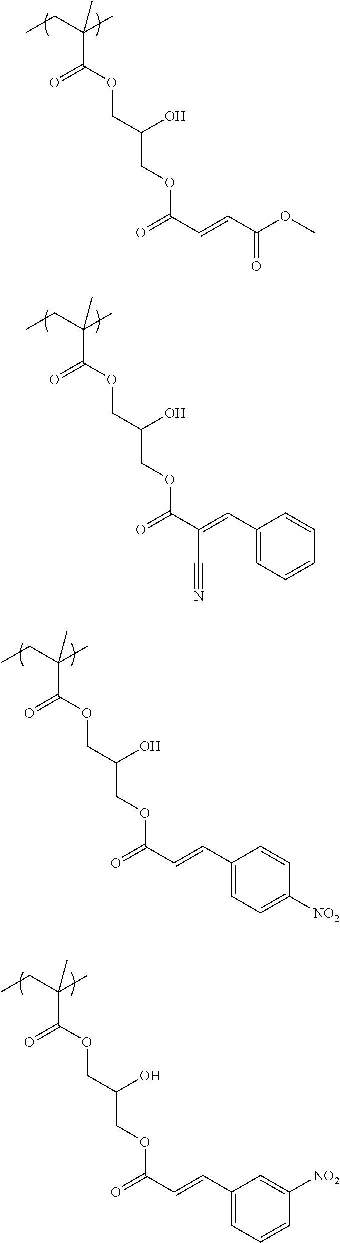

As an example, the polymer (A) containing the structural unit represented by Formula (1) can be formed, for example, by reacting a compound (C1) having a polymerizable multiple bond and a carboxy group with a glycidyl (meth)acrylate-based polymer as described below. The glycidyl (meth)acrylate-based polymer may be a homopolymer or a copolymer. Examples of the copolymer include a copolymer of glycidyl (meth)acrylate and 2-hydroxyethyl (meth)acrylate and a copolymer of glycidyl (meth)acrylate and 2-hydroxypropyl (meth)acrylate.

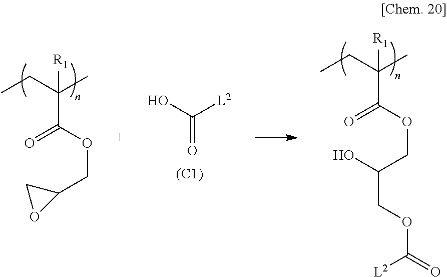

In the Formula, R¹ and L² are synonymous with R¹ and L² in Formula (1), respectively.

The reaction can be performed, for example, in the presence of a catalyst such as tetrabutylphosphonium bromide.

Examples of the compound (C1) having a polymerizable multiple bond and a carboxy group include acrylic acid, methacrylic acid, 4-vinylbenzoic acid, sorbic acid, tetrolic acid, tiglic acid, 1-cyclohexene-1-carboxylic acid, 2-benzylacrylic acid, trans-cinnamic acid, trans-4-methoxycinnamic acid, α-phenylcinnamic acid, monomethyl fumarate, α-cyanocinnamic acid, 4-nitrocinnamic acid, and 3-nitrocinnamic acid.

As another example, the polymer (A) containing the structural unit represented by Formula (1) can be formed, for example, by reacting a compound (C2) having a polymerizable multiple bond and an isocyanate group with a (meth)acrylate-based polymer having a hydroxy group as described below. The (meth)acrylate-based polymer having a hydroxy group may be a homopolymer or a copolymer.

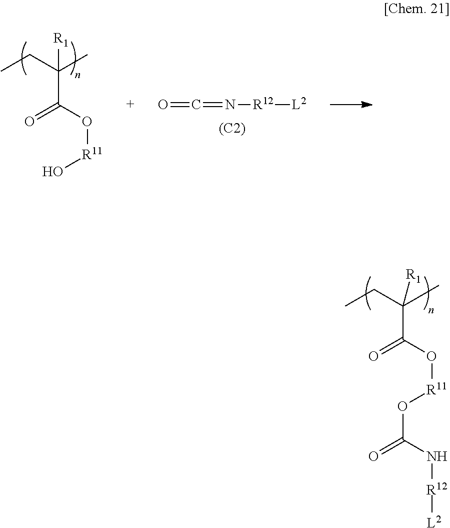

In the Formula, R¹ and L² are synonymous with R¹ and L² in Formula (1), respectively, R¹¹ represents a divalent organic group, and R¹² represents a single bond or a divalent organic group.

R¹¹ is, for example, an alkylene group having 1 to 4 carbon atoms.

R¹² is, for example, a single bond or an alkylene group having 1 to 4 carbon atoms.

As another example, the polymer (A) containing the structural unit represented by Formula (1) can be formed, for example, by reacting a compound (C2) having a polymerizable multiple bond and an isocyanate group with a styrene-based polymer having a hydroxy group or an amino group as described below. The styrene-based polymer having a hydroxy group or an amino group may be a homopolymer or a copolymer.

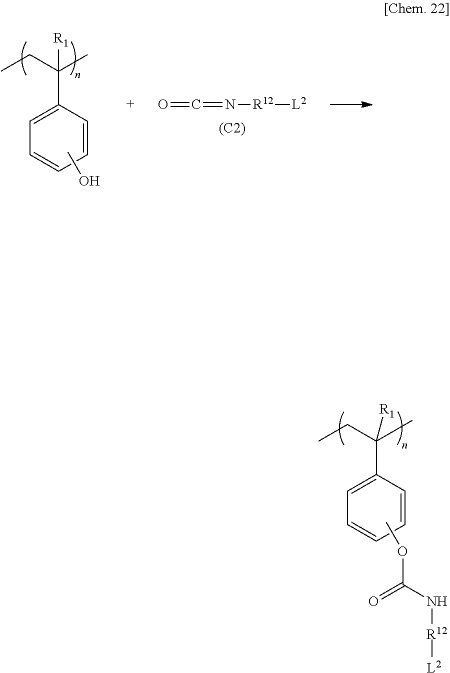

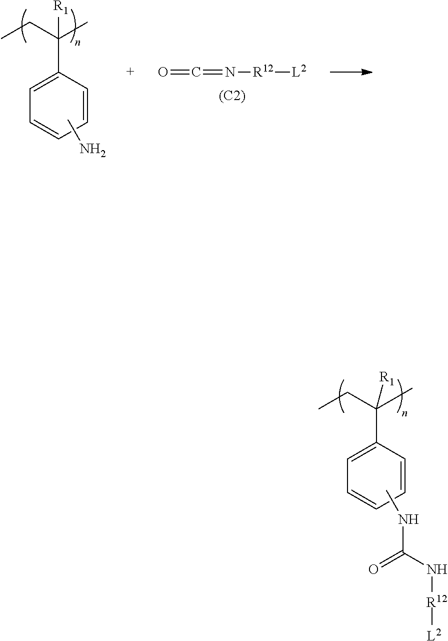

In the Formula, R¹ and L² are synonymous with R and L in Formula (1), respectively, R¹² represents a single bond or a divalent organic group.

R¹² is, for example, a single bond or an alkylene group having 1 to 4 carbon atoms.

Examples of the compound (C2) having a polymerizable multiple bond and an isocyanate group include the following compounds:

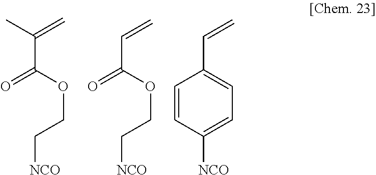

The polymer (A) may have a structural unit other than the structural unit represented by Formula (1). Examples of such a structural unit include a structural unit represented by the following Formula (2) and a structural unit represented by the following Formula (3):

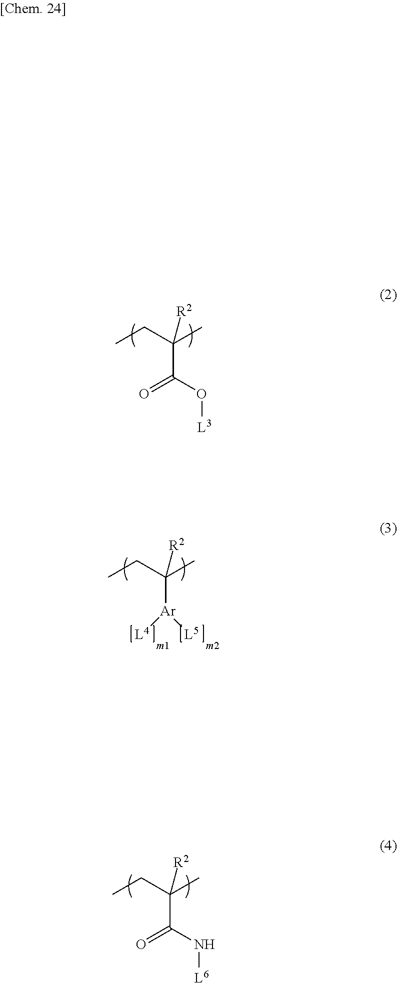

where in Formula (2), R² represents a hydrogen atom or an alkyl group having 1 to 10 carbon atoms, and L³ represents a monovalent group having 1 to 20 carbon atoms;
in Formula (3), R² represents a hydrogen atom or an alkyl group having 1 to 10 carbon atoms, Ar represents a benzene ring or a naphthalene ring, and L⁴ represents a hydroxy group, a cyano group, a nitro group, or an amino group (—NH₂); L⁵ represents a halogen atom, an alkyl group having 1 to 6 carbon atoms, or an alkoxy group having 1 to 6 carbon atoms; ml represents an integer of 0 to 3; m2 represents an integer of 0 to 5; provided that the sum of m1 and m2 is 0 to 5; when m1 is 2 or 3, a plurality of L⁴s may be identical to or different from each other or one another; when m2 is 2 to 5, a plurality of L's may be identical to or different from each other or one another;
in Formula (4), R² represents a hydrogen atom or an alkyl group having 1 to 10 carbon atoms, L¹ represents a monovalent organic group selected from an alkyl group having 1 to 10 carbon atoms and an aryl group having 6 to 40 carbon atoms, and at least one hydrogen atom of the alkyl group and the aryl group is optionally substituted with a hydroxy group or an alkoxy group having 1 to 6 carbon atoms.

The monovalent group having 1 to 20 carbon atoms in L³ in Formula (2) represents, for example, a monovalent organic group selected from an alkyl group having 1 to 10 carbon atoms and an aryl group having 6 to 40 carbon atoms, and at least one hydrogen atom of the alkyl group and the aryl group is optionally substituted with a hydroxy group. In the alkyl group, an oxygen atom may be inserted between a carbon atom and a carbon atom.

Examples of the monovalent group having 1 to 20 carbon atoms in L³ include a group represented by the following Formula (2-1):

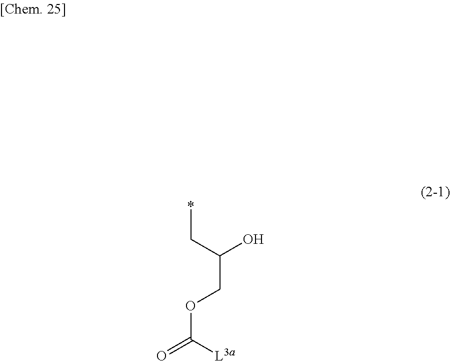

where in Formula (2-1), L^{3a} represents an optionally substituted alkyl group having 1 to 6 carbon atoms or an optionally substituted aromatic hydrocarbon group.

Examples of the aromatic hydrocarbon group in L^{3a} include a phenyl group and a naphthyl group.

Examples of the substituent in the optionally substituted alkyl group having 1 to 6 carbon atoms in L^{3a} include a halogen atom and a hydroxy group. The number of substituents may be 1 or more. When a plurality of substituents is present, the plurality of substituents may be identical to or different from one another.

Examples of the substituent in the optionally substituted aromatic hydrocarbon group in L^{3a} include a halogen atom, a hydroxy group, and an alkyl group having 1 to 3 carbon atoms optionally substituted with a halogen atom. The number of substituents may be 1 or more. When a plurality of substituents is present, the plurality of substituents may be identical to or different from one another.

Specific examples of the alkyl group having 1 to 10 carbon atoms represented by R² and the alkyl group having 1 to 10 carbon atoms represented by L³ and L¹ are as described above.

Examples of the halogen atom in L⁵ include a fluorine atom, a chlorine atom, a bromine atom, and an iodine atom. Examples of the alkyl group having 1 to 6 carbon atoms in L⁵ include a methyl group, an ethyl group, an n-propyl group, an i-propyl group, a cyclopropyl group, an n-butyl group, and an i-butyl group.

Examples of the alkoxy group having 1 to 6 carbon atoms in L⁵ include a methoxy group, an ethoxy group, a propoxy group, and a butoxy group.

m1 represents an integer of 0 to 3, and may be 0, 1, 2, or 3.

m2 represents an integer of 0 to 5, and may be 0, 1, 2, 3, 4, or 5.

Examples of the aryl group having 6 to 40 carbon atoms represented by L³ and L⁶ include a phenyl group, an o-methylphenyl group, an m-methylphenyl group, a p-methylphenyl group, an o-chlorophenyl group, a m-chlorophenyl group, a p-chlorophenyl group, an o-fluorophenyl group, a p-fluorophenyl group, an o-methoxyphenyl group, a p-methoxyphenyl group, a p-nitrophenyl group, a p-cyanophenyl group, an x-naphthyl group, a B-naphthyl group, an o-biphenylyl group, a m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, and a 9-phenanthryl group.

Examples of the alkoxy group having 1 to 6 carbon atoms in L⁶ include a methoxy group, an ethoxy group, a propoxy group, and a butoxy group.

Examples of the monomer used to derive Formula (2) include the following compounds:

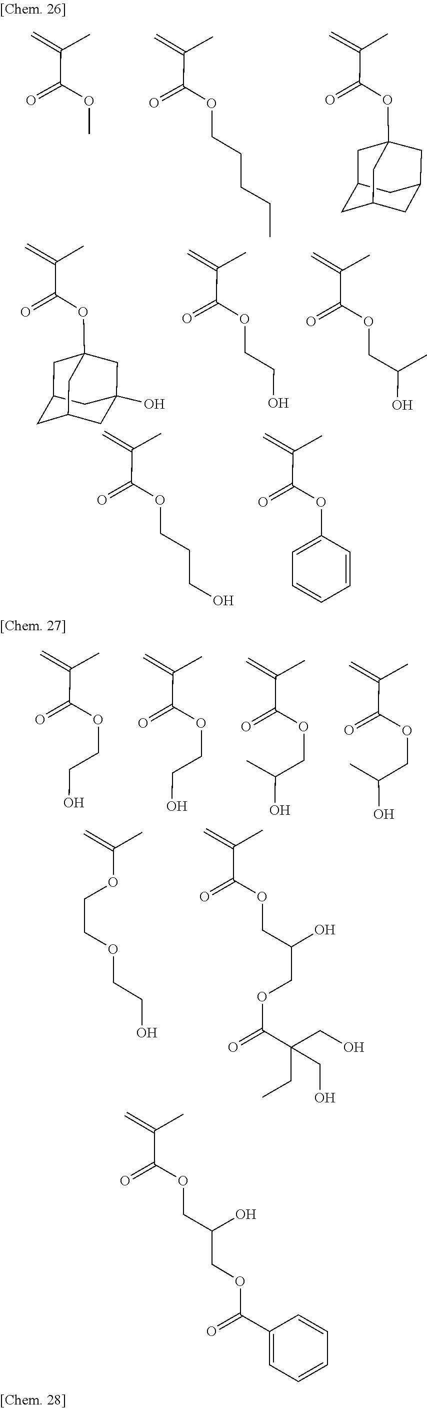

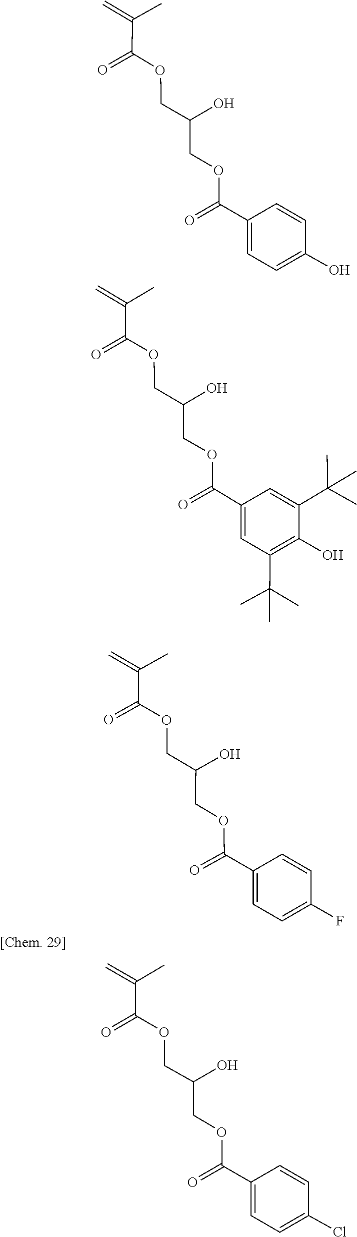

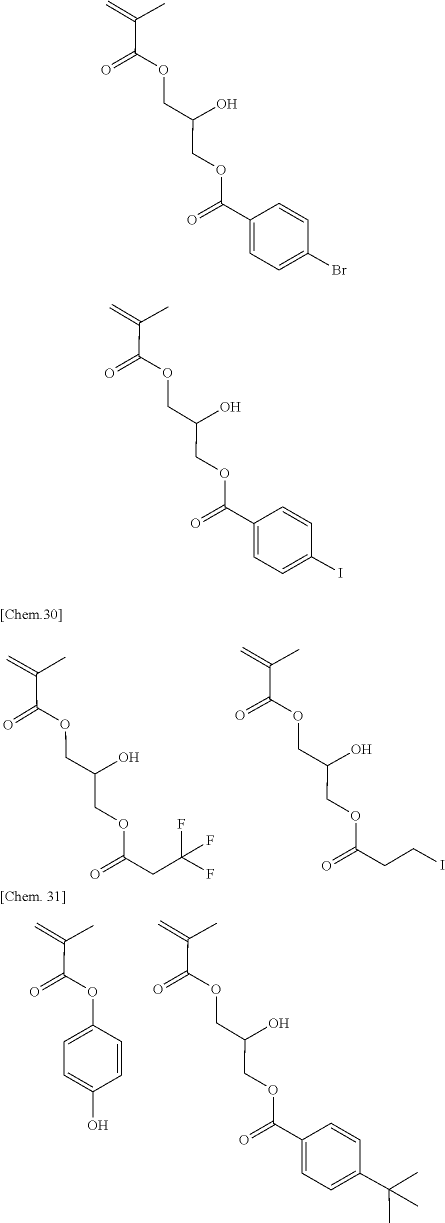 [SMILES: C=C(C)C(=O)OCC(O)COC(=O)c1ccc(Br)cc1 ; C=C(C)C(=O)OCC(O)COC(=O)c1ccc(I)cc1 ; C=C(C)C(=O)OCC(O)COC(=O)CC(F)(F)F ; C=C(C)C(=O)OCC(O)COC(=O)CCI ; C=C(C)C(=O)Oc1ccc(O)cc1 ; C=C(C)C(=O)OCC(O)COC(=O)c1ccc(C(C)(C)C)cc1]

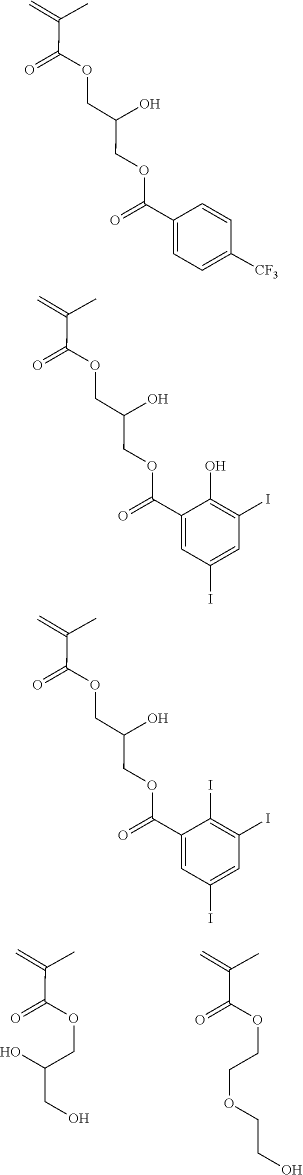

Examples of the monomer used to derive Formula (3) include the following compounds:

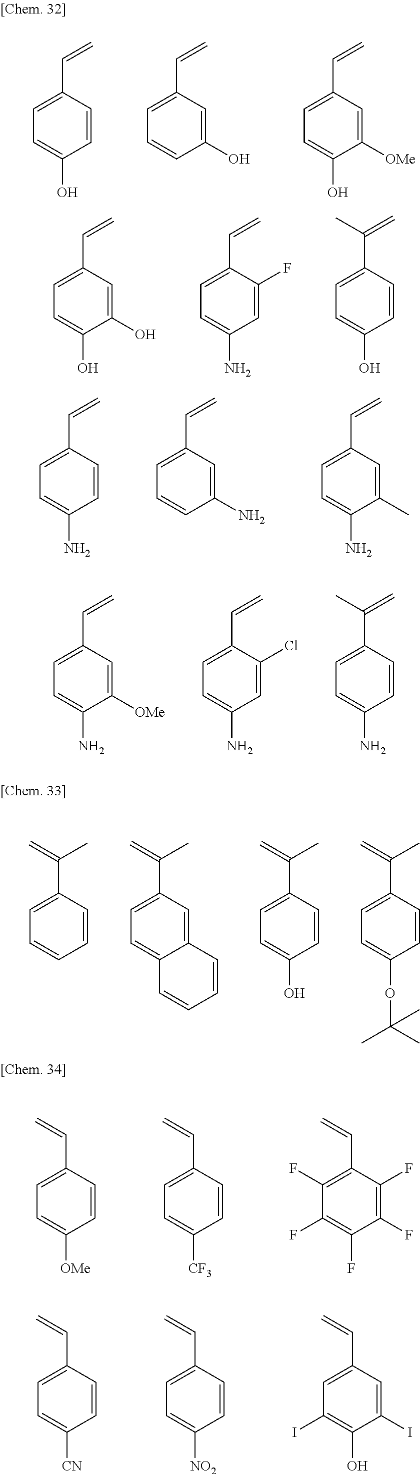

Me represents a methyl group.

Examples of the monomer used to derive Formula (4) include the following compounds:

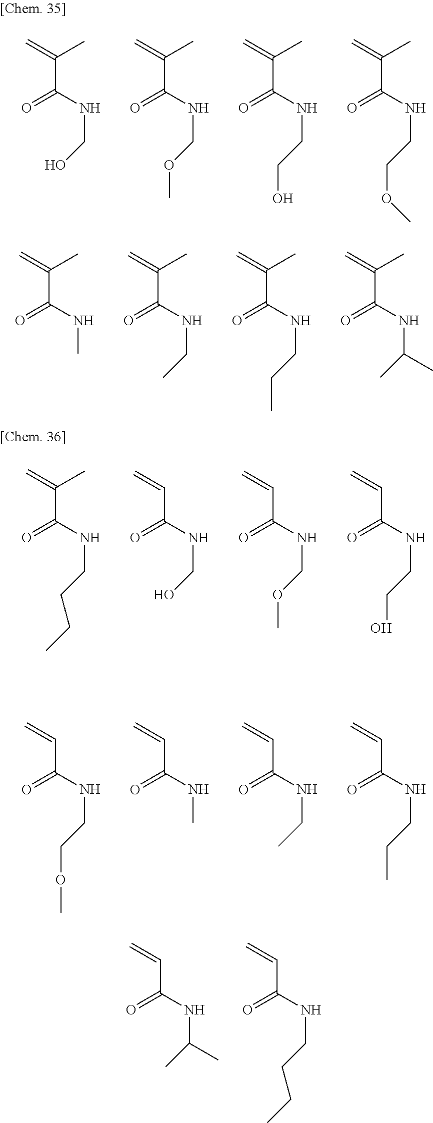

The ratio of the structural unit represented by Formula (1) in the polymer (A) is not particularly limited, and the molar ratio of the structural unit represented by Formula (1) may be, for example, 20 mol to 100 mol, or 20 mol or more and less than 100 mol, relative to all the structural units of the polymer (A).

The ratio of the structural unit represented by Formula (2) in the polymer (A) is not particularly limited, and the molar ratio of the structural unit represented by Formula (2) may be, for example, 0 mol % to 80 mol %, or may be more than 0 mol % and 80 mol % or less, relative to all the structural units of the polymer (A).

The polymer (A) may contain another structural unit other than the structural unit represented by Formula (1) and the structural unit represented by Formula (2). In that case, the molar ratio of the other structural unit to all the structural units of the polymer (A) is, for example, more than 0 mol % and 20 mol % or less.

The polymer (A) is not, for example, a polysiloxane.

The polymer (A) is not, for example, a hydrolysis condensate of a hydrolyzable silane.

The polymer (A) is not, for example, a reaction product of a tetracarboxylic dianhydride and a diepoxy compound having two epoxy groups.

The polymer (A) is not, for example, a reaction product of a tetracarboxylic dianhydride, a diepoxy compound having two epoxy groups, and a monohydroxy compound having one hydroxy group.

The polymer (A) does not have, for example, an isocyanuric acid skeleton having an alkenyl group. Examples of the alkenyl group include an alkenyl group having 3 to 6 carbon atoms. Examples of the alkenyl group having 3 to 6 carbon atoms include an allyl group.

The molecular weight of the polymer (A) is not particularly limited.

The lower limit of the weight-average molecular weight of the polymer (A) is, for example, 500, 1,000, 2,000, or 3,000.

The upper limit of the weight-average molecular weight of the polymer (A) is, for example, 100,000, 50,000, 30,000, 20,000, or 10,000.

### <Solvent>

The solvent to be used in the resist underlayer film-forming composition is not particularly limited as long as it is a solvent that can uniformly dissolve a component contained in the polymer (A) or the like, and an organic solvent generally used in a chemical for a semiconductor lithography process is preferred. Specific examples of the solvent include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, y-butyrolactone, N-methylpyrrolidone, N, N-dimethylformamide, and N, N-dimethylacetamide. The solvents may be used singly or in combination of two or more kinds thereof.

Among these solvents, propylene glycol monomethyl ether, propylene glycol monomethyl ether acetate, ethyl lactate, butyl lactate, methyl 2-hydroxyisobutyrate, and cyclohexanone are preferred. Particularly, propylene glycol monomethyl ether and propylene glycol monomethyl ether acetate are preferred.

### <Acid Generator>

As the acid generator contained as an optional component in the resist underlayer film-forming composition, both a thermal acid generator and a photoacid generator can be used. Preferably, the thermal acid generator is used.

Examples of the thermal acid generator include sulfonic acid compounds and carboxylic acid compounds such as p-toluenesulfonic acid, trifluoromethanesulfonic acid, pyridinium-p-toluenesulfonate (pyridinium-p-toluenesulfonic acid), pyridinium phenolsulfonic acid, pyridinium-p-hydroxybenzenesulfonic acid (p-phenolsulfonic acid pyridinium salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photoacid generator include an onium salt compound, a sulfonimide compound, and a disulfonyldiazomethane compound.

Specific examples of the onium salt compound include, but are not limited to, iodonium salt compounds, such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-tert-butylphenyl) iodonium camphorsulfonate, and bis(4-tert-butylphenyl) iodonium trifluoromethanesulfonate; and sulfonium salt compounds, such as triphenylsulfonium hexafluoroantimonate, triphenylsulfonium nonafluoro normal butanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoro normal butane sulfonyloxy)succinimide, N-(camphorsulfonyloxy)succinimide, and N-(trifluoromethanesulfonyloxy) naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis (p-toluenesulfonyl)diazomethane, bis(2,4-dimethylbenzenesulfonyl)diazomethane, and methylsulfonyl-p-toluenesulfonyldiazomethane.

The acid generators can be used singly or in combination two or more kinds thereof.

When an acid generator is used, the content ratio of the acid generator is, for example, 0.1 mass % to 50 mass %, preferably 1 mass % to 30 mass % relative to the crosslinking agent.

### <Crosslinking Agent>

The crosslinking agent is not particularly limited.

Examples of the crosslinking agent include compounds having two or more of the following structures.

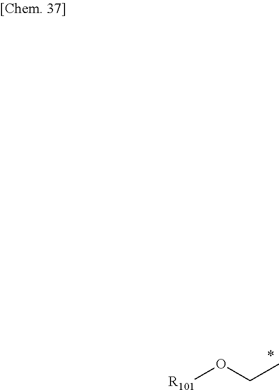

In the structure, R₁₀₁ represents a hydrogen atom, an alkyl group having 1 to 4 carbon atoms, or an alkoxyalkyl group having 2 to 6 carbon atoms. An asterisk * represents a bonding hand.

The bonding hand is bonded to, for example, a nitrogen atom, a carbon atom constituting an aromatic hydrocarbon ring, or the like.

As R₁₀₁, a hydrogen atom, a methyl group, an ethyl group, or a group represented by the following structure is preferred.

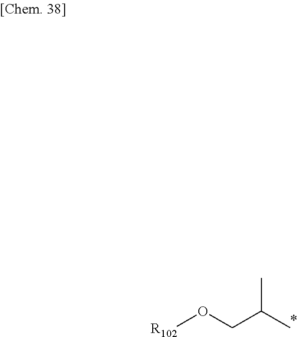

In the structure, R₁₀₂ represents a hydrogen atom, a methyl group, or an ethyl group. An asterisk * represents a bonding hand.

The crosslinking agent is preferably a melamine compound, a guanamine compound, a glycoluril compound, a urea compound, or a compound having a phenolic hydroxy group. These compounds can be used singly or in combination of two or more kinds thereof.

The melamine compound is not particularly limited as long as it is a melamine compound having a group that can react with a hydroxy group.

Examples of the melamine compound include hexamethylolmelamine, hexamethoxymethylmelamine, a compound in which 1 to 6 methylol groups of hexamethylolmelamine are methoxymethylated or a mixture thereof, hexamethoxyethylmelamine, hexaacyloxymethylmelamine, and a compound in which 1 to 6 methylol groups of hexamethylolmelamine are acyloxymethylated or a mixture thereof.

The guanamine compound is not particularly limited as long as it is a guanamine compound having a group that can react with a hydroxy group.

Examples of the guanamine compound include tetramethylolguanamine, tetramethoxymethylguanamine, a compound in which 1 to 4 methylol groups of tetramethylolguanamine are methoxymethylated or a mixture thereof, tetramethoxyethylguanamine, tetraacyloxyguanamine, and a compound in which 1 to 4 methylol groups of tetramethylolguanamine are acyloxymethylated or a mixture thereof.

The glycoluril compound is not particularly limited as long as it is a glycoluril compound having a group that can react with a hydroxy group.

Examples of the glycoluril compound include tetramethylolglycoluril, tetramethoxyglycoluril, tetramethoxymethylglycoluril, a compound in which 1 to 4 methylol groups of tetramethylolglycoluril are methoxymethylated or a mixture thereof, and a compound in which 1 to 4 methylol groups of tetramethylolglycoluril are acyloxymethylated or a mixture thereof.

The glycoluril compound may be, for example, a glycoluril derivative represented by the following Formula (1E):

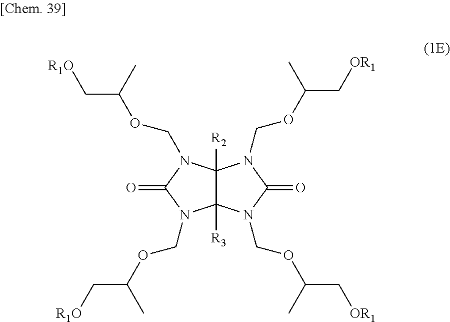

where in Formula (1E), 4 R₁s each independently represent a methyl group or an ethyl group, and R₂ and R₃ each independently represent a hydrogen atom, an alkyl group having 1 to 4 carbon atoms, or a phenyl group.

Examples of the glycoluril derivative represented by Formula (1E) above include compounds represented by the following Formulae (1E-1) to (1E-6):

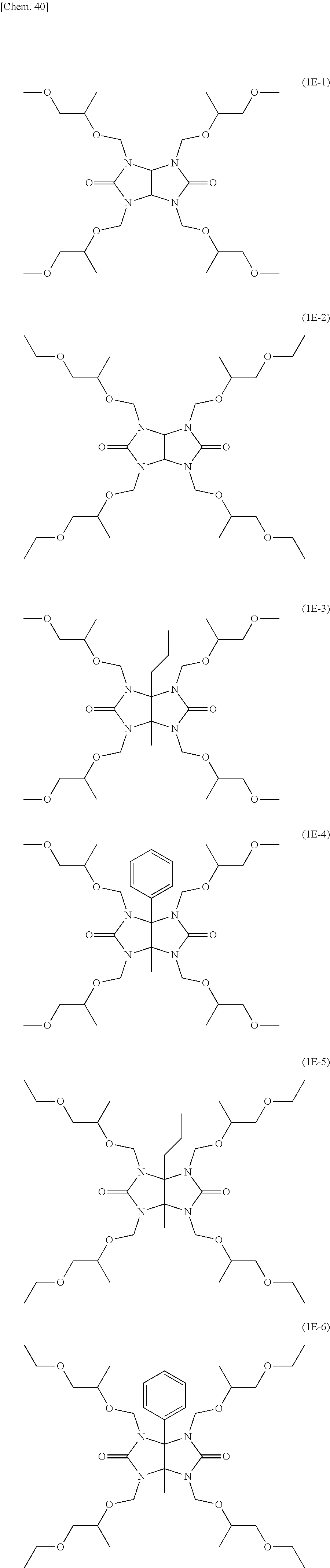

The glycoluril derivative represented by Formula (1E) is prepared by reacting a glycoluril derivative represented by the following Formula (2E) with at least one compound represented by the following Formula (3d):

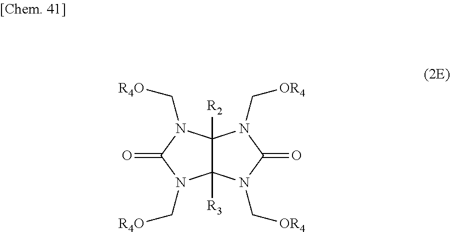

where in Formula (2E), R₂ and R₃ each independently represent a hydrogen atom, an alkyl group having 1 to 4 carbon atoms, or a phenyl group, and Ras each independently represent an alkyl group having 1 to 4 carbon atoms;

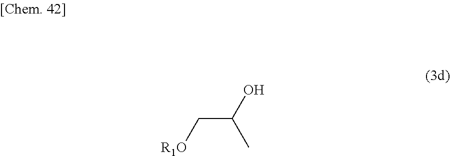

where in Formula (3d), Ri represents a methyl group or an ethyl group.

Examples of the glycoluril derivative represented by Formula (2E) above include compounds represented by Formulae (2E-1) to (2E-4) described below. Further, examples of the compound represented by Formula (3d) above include compounds represented by the following Formulae (3d-1) and (3d-2) described below.

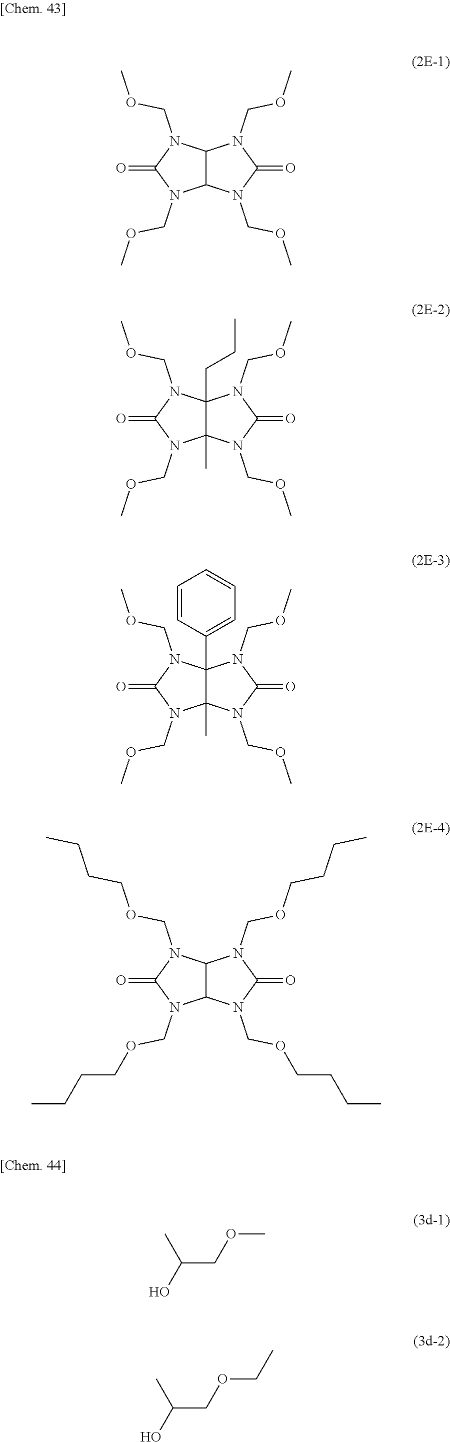

The urea compound is not particularly limited as long as it is a urea compound having a group that can react with a hydroxy group.

Examples of the urea compound include tetramethylol urea, tetramethoxy methyl urea, a compound in which 1 to 4 methylol groups of tetramethylol urea are methoxymethylated or a mixture thereof, and tetramethoxy ethyl urea.

Examples of the compound having a phenolic hydroxy group include compounds represented by the following Formula (111) or Formula (112):

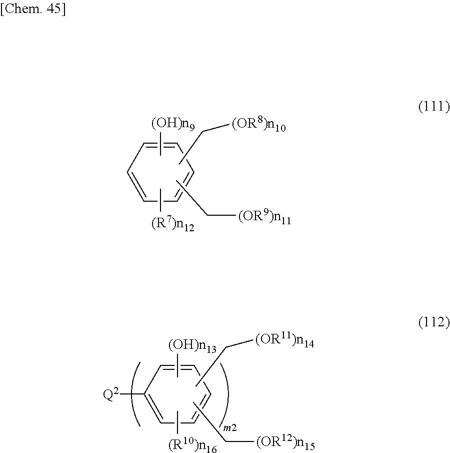

where in Formulae (111) and (112), Q² represents a single bond or an m2-valent organic group;
R², R⁹, R¹, and R¹ each represent a hydrogen atom or a methyl group;
R⁷ and R¹⁰ each represent an alkyl group having 1 to 10 carbon atoms or an aryl group having 6 to 40 carbon atoms;
n₉ represents an integer that meets 1≤n₉≤3, n₁₀ represents an integer that meets 2≤n₁₀≤5, n₁₁ represents an integer that meets 0≤n₁₁≤3, and n₁₂ represents an integer that meets 0≤n₁₂≤3, and an integer that meets 3≤(n₉+n₁₀+n₁₁+n₁₂)≤6;
n₁₃ represents an integer that meets 1≤n₁₃≤3, n₁₄ represents an integer that meets 1≤n₁₄≤4, n₁₅ represents an integer that meets 0≤n₁₅≤3, and n₁₆ represents an integer that meets 0≤n₁₆≤3, and an integer that meets 2≤(n₁₃+n₁₄+n₁₅+n₁₆)≤5; and
m2 represents an integer of 2 to 10.

Examples of the organic group in Q² include an m2-valent organic group having 1 to 4 carbon atoms.

Examples of the compound represented by Formula (111) or (112) include the following compounds:

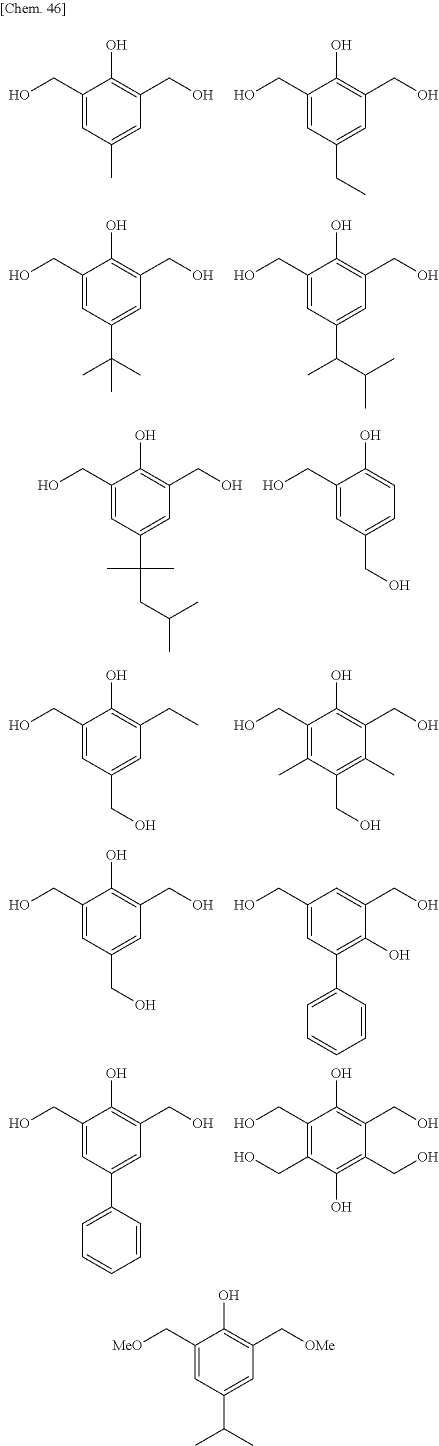

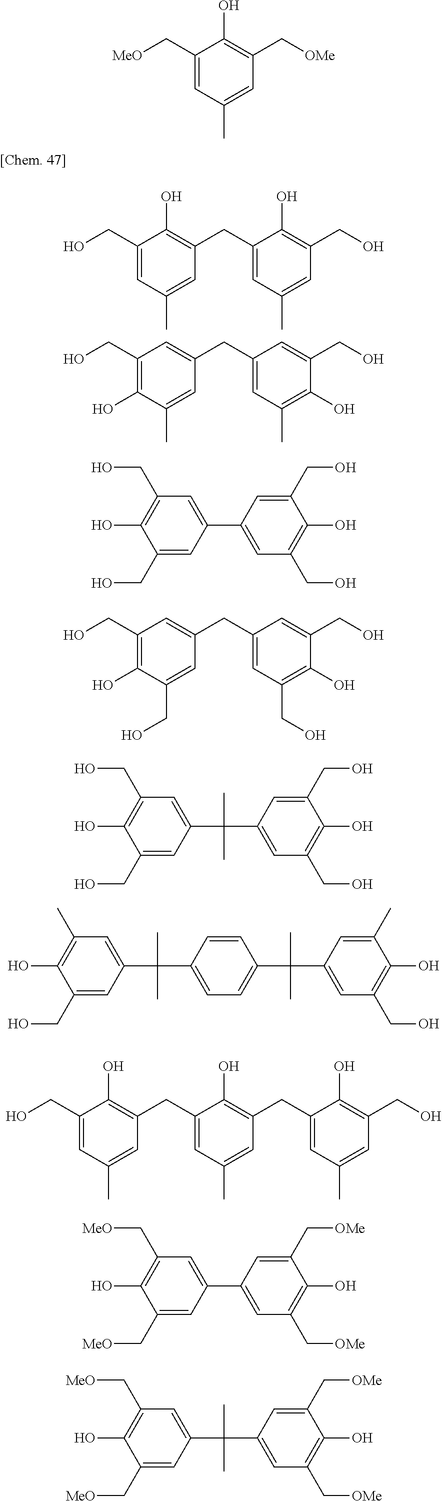

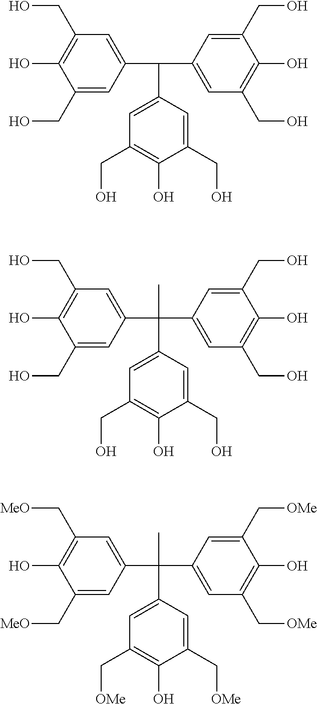 [SMILES: OCc1cc(C(c2cc(CO)c(O)c(CO)c2)c2cc(CO)c(O)c(CO)c2)cc(CO)c1O ; CC(c1cc(CO)c(O)c(CO)c1)(c1cc(CO)c(O)c(CO)c1)c1cc(CO)c(O)c(CO)c1 ; COCc1cc(C(C)(c2cc(COC)c(O)c(COC)c2)c2cc(COC)c(O)c(COC)c2)cc(COC)c1O]

The compounds are available as products of Asahi Organic Chemicals Industry Co., Ltd. and Honshu Chemical Industry Co., Ltd. Examples of the products include TMOM-BP (trade name) manufactured by Asahi Organic Chemicals Industry Co., Ltd.

Among the compounds, the glycoluril compound is preferred. Specifically, tetramethylolglycoluril, tetramethoxyglycoluril, tetramethoxymethylglycoluril, a compound in which 1 to 4 methylol groups of tetramethylolglycoluril are methoxymethylated or a mixture thereof, and a compound in which 1 to 4 methylol groups of tetramethylolglycoluril are acyloxymethylated or a mixture thereof are preferred, tetramethoxymethylglycoluril is preferred.

The molecular weight of the crosslinking agent is not particularly limited, and is preferably 500 or less.

The content of the crosslinking agent in the resist underlayer film-forming composition is not particularly limited, and is, for example, 1 mass % to 50 mass %, preferably 5 mass % to 40 mass %, relative to the polymer (A).

### <Thermal Radical Polymerization Initiator>

The polymerizable multiple bond of the polymer (A) is polymerized by heating even in the absence of a thermal radical polymerization initiator, for example. Accordingly, the resist underlayer film-forming composition need not contain a thermal radical polymerization initiator. Polymerization of the polymerizable multiple bond may be initiated by radicals generated by thermal decomposition of additives such as a polymer, a solvent, and a crosslinking agent in the composition or impurities contained therein.

The resist underlayer film-forming composition not containing a thermal radical polymerization initiator has excellent storage stability as compared with the resist underlayer film-forming composition containing a thermal radical polymerization initiator. Therefore, it is preferable that the content ratio of the thermal radical polymerization initiator in the resist underlayer film-forming composition is small. The content ratio of the thermal radical polymerization initiator in the resist underlayer film-forming composition is preferably 0 mass % to 1 mass %, more preferably 0 mass % to 0.5 mass %, and particularly preferably 0 mass % to 0.1 mass % relative to the polymer (A).

Examples of the thermal radical polymerization initiator include peroxides, azo-based compounds, and persulfates.

Examples of the peroxides include acetyl peroxide, benzoyl peroxide, methyl ethyl ketone peroxide, cyclohexanone peroxide, hydrogen peroxide, tert-butyl hydroperoxide, cumene hydroperoxide, di-tert-butyl peroxide, dicumyl peroxide, dilauroyl peroxide, tert-butyl peroxyacetate, tert-butyl peroxypivalate, and tert-butyl peroxy-2-ethylhexanoate (tert-butyl 2-ethylhexaneperoxoate).

Examples of the azo-based compounds include 2,2′-azobisisobutyronitrile, 2,2′-azobis(2,4-dimethylvaleronitrile), (1-phenylethyl)azodiphenylmethane, 2,2′-azobis(4-methoxy-2,4-dimethylvaleronitrile), dimethyl 2,2′-azobisisobutyrate, 2,2′-azobis(2-methylbutyronitrile), 1,1′-azobis(1-cyclohexanecarbonitrile), 2-(carbamoylazo)isobutyronitrile, 2,2′-azobis(2,4,4-trimethylpentane), 2-phenylazo-2,4-dimethyl-4-methoxyvaleronitrile, and 2,2′-azobis(2-methylpropane).

Examples of the persulfates include ammonium persulfate, sodium persulfate, and potassium persulfate.

The thermal radical polymerization initiator may be a commercially available product.

### <Additional Component>

In the resist underlayer film-forming composition, a surfactant can be further added in order not to generate pinholes, striation, and the like and to further improve the application property against surface irregularity.

Further, any polymer other than the polymer (A) can be added. Examples thereof include a polymer described in WO 2013/018802 A and a polymer containing hydroxyarene.

Specific examples of the surfactant include, but are not limited to, nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylallyl ethers, such as polyoxyethylene octylphenol ether and polyoxyethylene nonylphenol ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants, such as EFTOP EF301, EF303, and EF352 (trade names, manufactured by Tohkem Products Corporation), MEGAFACE F171, F173, and R-30 (trade names, manufactured by DIC Corporation), Fluorad FC430 and FC431 (trade names, manufactured by Sumitomo 3M Limited), AsahiGuard AG710 (trade name, manufactured by AGC Inc.), and SURFLON 5-382, SC101, SC102, SC103, SC104, SC105, and SC106 (trade names, manufactured by AGC Inc.); and Organosiloxane Polymer KP341 (manufactured by Shin-Etsu Chemical Co., Ltd.).

The amount of each of these surfactants added is ordinarily 2.0 mass % or less, and preferably 1.0 mass % or less relative to the total solid content of the resist underlayer film-forming composition.

These surfactants may be added singly, or in combination of two or more kinds thereof.

The amount of the solid content in the resist underlayer film-forming composition of the present invention, i.e. the components excluding the solvent is, for example, 0.01 mass % to 10 mass %.

### (Resist Underlayer Film)

The resist underlayer film of the present invention is a cured product of the resist underlayer film-forming composition described above.

The resist underlayer film can be produced, for example, by applying the resist underlayer film-forming composition described above onto a semiconductor substrate and baking the composition.

Examples of the semiconductor substrate to which the resist underlayer film-forming composition is applied include a silicon wafer, a germanium wafer, and a semiconductor wafer formed of a compound such as gallium arsenide, indium phosphide, gallium nitride, indium nitride, or aluminum nitride.

When a semiconductor substrate having an inorganic film formed on a surface thereof is used, the inorganic film is formed by, for example, an atomic layer deposition (ALD) method, a chemical vapor deposition (CVD) method, a reactive sputtering method, an ion plating method, a vacuum deposition method, or a spin coating method (spin-on glass: SOG). Examples of the inorganic film include a polysilicon film, a silicon oxide film, a silicon nitride film, a boro-phospho silicate glass (BPSG) film, a titanium nitride film, a titanium nitride oxide film, a tungsten film, a gallium nitride film, and a gallium arsenide film.

The resist underlayer film-forming composition of the present invention is applied onto the semiconductor substrate by an appropriate application method such as a spinner or a coater. Thereafter, the resultant semiconductor substrate is baked using a heating means such as a hot plate to form a resist underlayer film. The conditions for baking are appropriately selected from a baking temperature of 100° C. to 400° C. and a baking time of 0.3 minutes to 60 minutes. Preferably, the baking temperature is 120° C. to 350° C. and the baking time is 0.5 minutes to 30 minutes. More preferably, the baking temperature is 150° C. to 300° C. and the baking time is 0.8 minutes to 10 minutes.

The film thickness of the resist underlayer film is, for example, 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (3 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), 0.005 μm (5 nm) to 0.02 μm (20 nm), 0.005 μm (5 nm) to 0.02 μm (20 nm), 0.003 μm (3 nm) to 0.01 μm (10 nm), 0.005 μm (5 nm) to 0.01 μm (10 nm), 0.003 μm (3 nm) to 0.006 μm (6 nm), or 0.005 μm (5 nm).

The method for measuring the film thickness of the resist underlayer film in the present specification is as follows.
Measurement apparatus name: Ellipsometric Film Thickness Measurement System RE-3100 (SCREEN Semiconductor Solutions Co., Ltd.)
Single wavelength ellipsometer (SWE) mode
Arithmetic average of eight points (e.g. eight points are measured at intervals of 1 cm in the X direction of the wafer.)

### (Laminate)

The laminate of the present invention includes a semiconductor substrate and the resist underlayer film of the present invention.

Examples of the semiconductor substrate include the semiconductor substrates described above.

The resist underlayer film is disposed on the semiconductor substrate, for example.

### (Method for Producing Semiconductor Element, and Method for Forming Pattern)

The method for producing a semiconductor element of the present invention includes at least the following steps:
step of forming a resist underlayer film on a semiconductor substrate using the resist underlayer film-forming composition of the present invention; and
step of forming a resist film on the resist underlayer film.

The method for forming a pattern of the present invention includes at least the following steps:
step of forming a resist underlayer film on a semiconductor substrate using the resist underlayer film-forming composition of the present invention;
step of forming a resist film on the resist underlayer film;
step of irradiating the resist film with light or an electron beam, and then developing the resist film to form a resist pattern; and
step of etching the resist underlayer film using the resist pattern as a mask.

Ordinarily, a resist layer is formed on the resist underlayer film.

The film thickness of the resist layer is preferably 200 nm or less, more preferably 150 nm or less, still more preferably 100 nm or less, and particularly preferably 80 nm or less. The film thickness of the resist layer is preferably 10 nm or more, more preferably 20 nm or more, and particularly preferably 30 nm or more.

The resist film formed on the resist underlayer film by a known method (e.g. applying and baking of resist) is not particularly limited as long as it responds to light or an electron beam (EB) used for irradiation. Both a negative photoresist and a positive photoresist can be used.

In the present specification, a resist responding to EB is also referred to as a photoresist.

Examples of the photoresist include a positive photoresist formed of a novolac resin and 1,2-naphthoquinone diazide sulfonic acid ester; a chemically amplified photoresist formed of a binder having a group that is decomposed by an acid to increase an alkali dissolution rate and a photoacid generator; a chemically amplified photoresist formed of a low molecular weight compound that is decomposed by an acid to increase an alkali dissolution rate of the photoresist, an alkali-soluble binder, and a photoacid generator; a chemically amplified photoresist formed of a binder having a group that is decomposed by an acid to increase an alkali dissolution rate, a low molecular weight compound having a group that is decomposed by an acid to increase an alkali dissolution rate of the photoresist, and photoacid generator; and a resist containing metal elements. Examples of the photoresist include V146G (trade name, manufactured by JSR Corporation), APEX-E (trade name, manufactured by Shipley Company L.L.C), PAR710 (trade name, manufactured by Sumitomo Chemical Co., Ltd.), and AR2772 and SEPR430 (trade name, manufactured by Shin-Etsu Chemical Co., Ltd.) Further, examples of the photoresist include a fluorine-containing atomic polymer-based photoresist as described in Proc. SPIE, Vol. 3999, 330-334 (2000), Proc. SPIE, Vol. 3999, 357-364 (2000), or Proc. SPIE, Vol. 3999, 365-374 (2000).

In addition, the resist compositions described in WO 2019/188595, WO 2019/187881, WO 2019/187803, WO 2019/167737, WO 2019/167725, WO 2019/187445, WO 2019/167419, WO 2019/123842, WO 2019/054282, WO 2019/058945, WO 2019/058890, WO 2019/039290, WO 2019/044259, WO 2019/044231, WO 2019/026549, WO 2018/193954, WO 2019/172054, WO 2019/021975, WO 2018/230334, WO 2018/194123, JP 2018-180525 A, WO 2018/190088A, JP 2018-070596 A, JP 2018-028090 A, JP 2016-153409 A, JP 2016-130240 A, JP 2016-108325 A, JP 2016-047920 A, JP 2016-035570 A, JP 2016-035567 A, JP 2016-035565 A, JP 2019-101417 A, JP 2019-117373 A, JP 2019-052294 A, JP 2019-008280 A, JP 2019-008279 A, JP 2019-003176 A, JP 2019-003175 A, JP 2018-197853 A, JP 2019-191298 A, JP 2019-061217 A, JP 2018-045152 A, JP 2018-022039 A, JP 2016-090441 A, JP 2015-10878 A, JP 2012-168279 A, JP 2012-022261 A, JP 2012-022258 A, JP 2011-043749 A, JP 2010-181857 A, JP 2010-128369 A, WO 2018/031896 A, JP 2019-113855 A, WO 2017/156388 A, WO 2017/066319 A, JP 2018-41099 A, WO 2016/065120 A, WO 2015/026482 A, JP 2016-29498 A, JP 2011-253185, and the like, the so-called resist compositions such as a radiation-sensitive resin composition and a high-resolution patterning composition based on an organometallic solution, and a metal-containing resist composition may be used, but are not limited thereto.

Examples of the resist composition include the following compositions:

An active ray-sensitive or radiation-sensitive resin composition containing: a resin A having a repeating unit having an acid-decomposable group in which a polar group is protected by a protecting group that is removed by an action of an acid; and a compound represented by the following Formula (121):

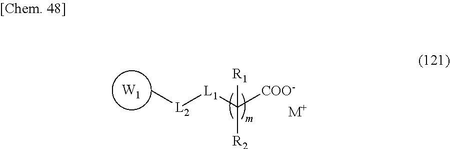

where in Formula (121), m represents an integer of 1 to 6,
R₁ and R₂ each independently represent a fluorine atom or a perfluoroalkyl group,
L₁ represents —O—, —S—, —COO—, —SO₂—, or —SO₃—,
L₂ represents an alkylene group which may have a substituent or a single bond,
W₁ represents a cyclic organic group which may have a substituent, and
M⁺ represents a cation.

A metal-containing film-forming composition for extreme ultraviolet ray or electron beam lithography, containing: a solvent and a compound having a metal-oxygen covalent bond, in which the metal elements constituting the compound belong to the third to seventh periods of Groups 3 to 15 of the periodic table.

A radiation-sensitive resin composition containing: an acid generator and a polymer having a first structural unit represented by the following Formula (31) and a second structural unit having an acid-dissociable group represented by the following Formula (32):

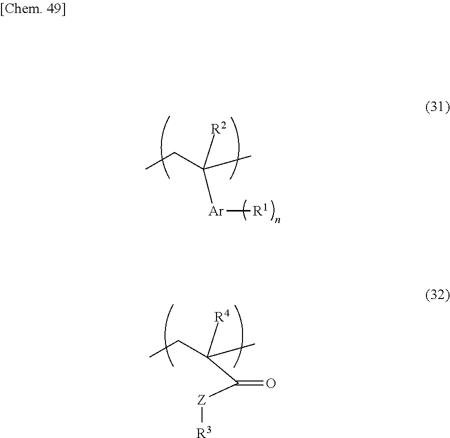

where in Formula (31), Ar is a group resulted from removal of (n+1) hydrogen atoms from arene having 6 to 20 carbon atoms; R¹ is a hydroxy group, a sulfanyl group, or a monovalent organic group having 1 to 20 carbon atoms, n is an integer of 0 to 11, when n is 2 or more, a plurality of R s is identical to or different from each other or one another, R² is a hydrogen atom, a fluorine atom, a methyl group, or a trifluoromethyl group, in Formula (32), R³ is a monovalent group having 1 to 20 carbon atoms and containing the acid-dissociable group, Z is a single bond, an oxygen atom, or a sulfur atom, and R⁴ is a hydrogen atom, a fluorine atom, a methyl group, or a trifluoromethyl group.

A resist composition containing: an acid generator and a resin (A1) having a structural unit having a cyclic carbonic acid ester structure, a structural unit represented by the following Formula, and a structural unit having an acid-unstable group:

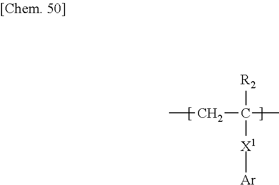

where,
R² represents an alkyl group having 1 to 6 carbon atoms which may have a halogen atom, a hydrogen atom, or a halogen atom, X¹ represents a single bond, —CO—O—*, or —CO—NR⁴—*, * represents a bonding hand with —Ar, R⁴ represents a hydrogen atom or an alkyl group having 1 to 4 carbon atoms, and Ar represents an aromatic hydrocarbon group having 6 to 20 carbon atoms which may have one or more groups selected from the group consisting of a hydroxy group and a carboxyl group.

Examples of the resist film include the following:

A resist film containing a base resin containing a repeating unit represented by the following Formula (a1) and/or a repeating unit represented by the following Formula (a2), and a repeating unit that generates an acid bonded to a polymer main chain upon exposure:

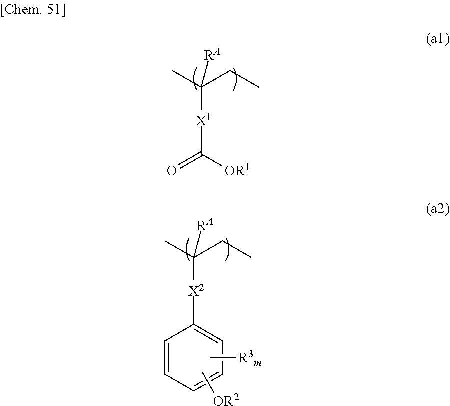

where in Formula (a1) and Formula (a2), R^{A}s each independently are a hydrogen atom or a methyl group, R¹ and R² are each independently a tertiary alkyl group having 4 to 6 carbon atoms, R³s each independently are a fluorine atom or a methyl group, m is an integer of 0 to 4, X¹ is a single bond, a phenylene group or a naphthylene group, or a linking group having 1 to 12 carbon atoms containing at least one selected from an ester bond, a lactone ring, a phenylene group, and a naphthylene group, and X² is a single bond, an ester bond, or an amide bond.

Examples of the resist material include the following:

A resist material including a polymer having a repeating unit represented by the following Formula (b1) or Formula (b2):

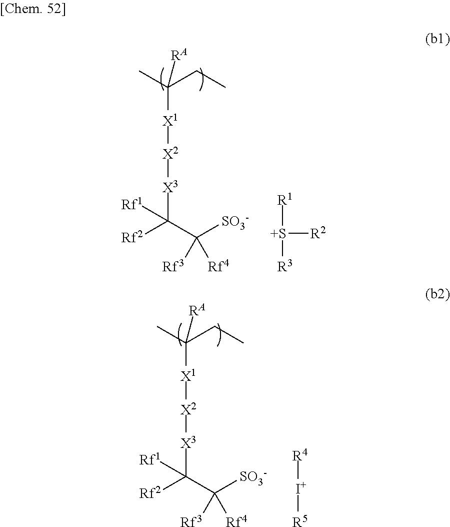

where in Formula (b1) and Formula (b2), R s each are a hydrogen atom or a methyl group; X¹ is a single bond or an ester group; X² is a linear, branched or cyclic alkylene group having 1 to 12 carbon atoms or an arylene group having 6 to 10 carbon atoms, a part of a methylene group constituting the alkylene group is optionally substituted with an ether group, an ester group or a lactone ring-containing group, and at least one hydrogen atom contained in X² is substituted with a bromine atom; X³ is a single bond, an ether group, an ester group, or a linear, branched or cyclic alkylene group having 1 to 12 carbon atoms, and a part of a methylene group constituting the alkylene group is optionally substituted with an ether group or an ester group; Rf¹ to Rf⁴ are each independently a hydrogen atom, a fluorine atom, or a trifluoromethyl group, and at least one of Rf¹ to Rf⁴ is a fluorine atom or a trifluoromethyl group; further, Rf¹ and Rf² may be combined to form a carbonyl group; R¹ to R⁵ are each independently a linear, branched or cyclic alkyl group having 1 to 12 carbon atoms, a linear, branched or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, and some or all of the hydrogen atoms in these groups are optionally substituted with a hydroxy group, a carboxy group, a halogen atom, an oxo group, a cyano group, an amide group, a nitro group, a sultone group, a sulfone group, or a sulfonium salt-containing group, and a part of a methylene group constituting each of these groups is optionally substituted with an ether group, an ester group, a carbonyl group, a carbonate group, or a sulfonic acid ester group; in addition, R¹ and R² may be bonded to form a ring together with the sulfur atom to which R¹ and R² are bonded.

A resist material including a base resin including a polymer having a repeating unit represented by the following Formula (a):

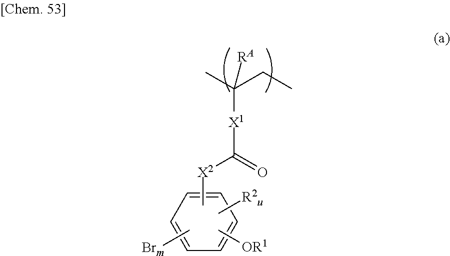

where in Formula (a), R^{A} is a hydrogen atom or a methyl group, R is a hydrogen atom or an acid-unstable group, R² is a linear, branched or cyclic alkyl group having 1 to 6 carbon atoms, or a halogen atom other than bromine, X¹ is a single bond or a phenylene group, or a linear, branched or cyclic alkylene group having 1 to 12 carbon atoms which may contain an ester group or a lactone ring, X² is —O—, —O—CH₂—, or —NH—, m is an integer of 1 to 4, and u is an integer of 0 to 3, provided that m+u is an integer of 1 to 4.

A resist composition which generates an acid by exposure and whose solubility in a developer is changed by an action of an acid, the resist composition containing:
a base material component (A) whose solubility in the developer is changed by an action of an acid; and a fluorine additive component (F) which is decomposable in an alkaline developer,
in which the fluorine additive component (F) contains a fluororesin component (F1) having a structural unit (f1) containing a base-dissociable group and a structural unit (f2) containing a group represented by the following Formula (f2-r-1):

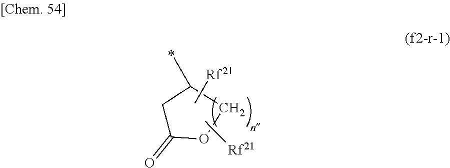

where in Formula (f2-r-1), Rf²¹s each independently represent a hydrogen atom, an alkyl group, an alkoxy group, a hydroxyl group, a hydroxyalkyl group, or a cyano group, n″ is an integer of 0 to 2, and an asterisk * is a bonding hand.

The structural unit (f1) includes a structural unit represented by the following Formula (f1-1) or a structural unit represented by the following Formula (f1-2):

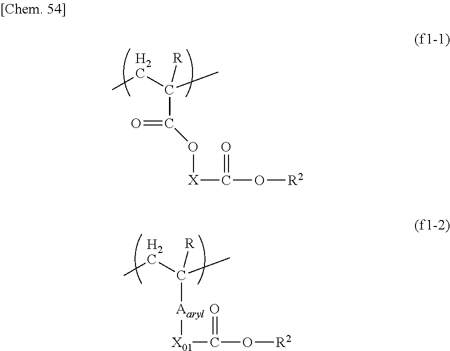

where in Formulae (f1-1) and (f1-2), Rs each independently represent a hydrogen atom, an alkyl group having 1 to 5 carbon atoms, or an alkyl halide group having 1 to 5 carbon atoms, X is a divalent linking group having no acid-dissociable site, A_{aryl} is a divalent aromatic cyclic group which may have a substituent, X₀₁ is a single bond or a divalent linking group, and R²s are each independently an organic group having a fluorine atom.

Examples of the coating, the coating solution, and the coating composition include the following:
A coating including a metal oxo-hydroxo network having organic ligand through a metal carbon bond and/or a metal carboxylate bond;
An inorganic oxo/hydroxo-based composition;
A coating solution containing: an organic solvent; a first organometallic composition represented by Formula R_{z}SnO_{(2-(z/2)-(x/2))}(OH)ₓ (where 0<z≤2 and 0<(z+x)≤4), Formula R′ₙSnX₄₋ₙ(where n=1 or 2), or a mixture thereof, where R and R′ are independently a hydrocarbyl group having 1 to 31 carbon atoms, and X is a ligand having a hydrolyzable bond to Sn or a combination thereof; and a hydrolyzable metal compound represented by MX′ᵥ (where M is a metal selected from Groups 2 to 16 of the periodic table of the elements, v=number of 2 to 6, and X′ is a ligand having a hydrolyzable M-X bond or a combination thereof);
A coating solution containing: an organic solvent; and a first organometallic compound represented by Formula RSnO_{(3/2-x/2)}(OH)ₓ (where 0<x<3), in which about 0.0025 M to about 1.5 M tin is contained in the solution, R is an alkyl group or cycloalkyl group having 3 to 31 carbon atoms, and the alkyl group or cycloalkyl group is bonded to tin via a secondary or tertiary carbon atom; and
An inorganic pattern forming precursor aqueous solution containing a mixture of water, a metal suboxide cation, a polyatomic inorganic anion, and a radiation-sensitive ligand containing a peroxide group.

Irradiation with light or an electron beam is performed, for example, through a mask (reticle) for forming a predetermined pattern. For example, an i-ray, a KrF excimer laser, an ArF excimer laser, an extreme ultraviolet ray (EUV), or an electron beam (EB) is used. The resist underlayer film-forming composition of the present invention is preferably applied for electron beam (EB) irradiation or extreme ultraviolet ray ((EUV): 13.5 nm) irradiation, and more preferably applied for extreme ultraviolet ray (EUV) exposure. The irradiation energy of the electron beam and the exposure amount of light are not particularly limited.

Post exposure bake (PEB) may be performed after the irradiation with light or electron beam and before development.

The baking temperature is not particularly limited, and is preferably 60° C. to 150° C., more preferably 70° C. to 120° C., and particularly preferably 75° C. to 110° C.

The baking time is not particularly limited, and is preferably 1 second to 10 minutes, more preferably 10 seconds to 5 minutes, and particularly preferably 30 seconds to 3 minutes.

For the development, for example, an alkaline developer is used.

The development temperature is, for example, 5° C. to 50° C.

The developing time is, for example, 10 seconds to 300 seconds.

Examples of the alkaline developer that can be used include aqueous solutions of alkalis, e.g. inorganic alkalis such as sodium hydroxide, potassium hydroxide, sodium carbonate, sodium silicate, sodium metasilicate, and ammonia water; primary amines such as ethylamine and n-propylamine; secondary amines such as diethylamine and di-n-butyl amine; tertiary amines such as triethylamine and methyldiethylamine; alcoholamines such as dimethylethanolamine and triethanolamine; quaternary ammonium salts such as tetramethylammonium hydroxide, tetraethylammonium hydroxide, and choline; and cyclic amines such as pyrrole and piperidine. Further, it is also possible to add an appropriate amount of alcohols such as isopropyl alcohol or surfactants such as a nonionic surfactant to the aqueous solution of the alkalis. Among these, a preferred developer is an aqueous solution of quaternary ammonium salt, more preferably an aqueous solution of tetramethylammonium hydroxide and an aqueous solution of choline. Furthermore, a surfactant or the like may be added to these developers. Instead of the method using the alkaline developer, a method in which development is conducted using an organic solvent, such as butyl acetate, can be used to develop the portion of the photoresist where the alkali dissolution rate is not improved.

Next, the resist underlayer film is etched using the formed resist pattern as a mask. The etching may be dry etching or wet etching, but is preferably dry etching.

When the inorganic film is formed on the surface of the used semiconductor substrate, the surface of the inorganic film is allowed to be exposed, whereas when the inorganic film is not formed on the surface of the used semiconductor substrate, the surface of the semiconductor substrate is allowed to be exposed. Thereafter, a semiconductor element can be produced through a step of processing the semiconductor substrate by a known method (dry etching method or the like).

### EXAMPLES

Next, the contents of the present invention will be specifically described with reference to Examples, but the present invention is not limited thereto.

The weight-average molecular weights of the polymers shown in Synthesis Examples below are results measured by gel permeation chromatography (hereinafter, abbreviated as GPC). For the measurement, a GPC apparatus manufactured by Tosoh Corporation was used, and measurement conditions and the like are as follows:
GPC column: Shodex KF803L, Shodex KF802, Shodex KF801 [registered trademark](Showa Denko K.K.)
Column temperature: 40° C.
Solvent: dimethylformamide (DMF)
Flow rate: 1.0 ml/min
Standard sample: polystyrene (manufactured by Tosoh Corporation)

### Synthesis Example 1

2.40 g of polyglycidyl methacrylate (manufactured by Maruzen Petrochemical Co., Ltd.), 1.46 g of methacrylic acid (manufactured by Tokyo Chemical Industry Co., Ltd.), 0.36 g of dibutyl hydroxy toluene (manufactured by Tokyo Chemical Industry Co., Ltd.), and 0.16 g of tetrabutylphosphonium bromide (manufactured by Hokko Chemical Industry Co., Ltd.) were added to and dissolved in 20 g of propylene glycol monomethyl ether acetate and 20 g of propylene glycol monomethyl ether in a reaction vessel. The reaction vessel was purged with nitrogen, and then the reaction was performed at 80° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer in the prepared polymer solution was subjected to GPC analysis, and found to have a weight-average molecular weight of 10660 in terms of standard polystyrene. The polymer prepared in this Synthesis Example has a structural unit represented by the following Formula (1a):

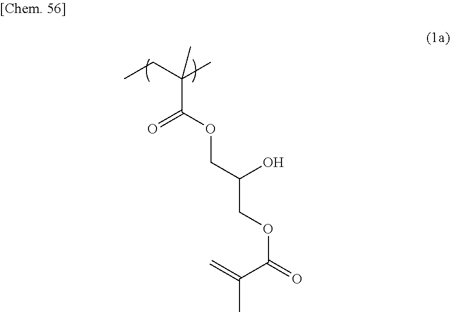

### Synthesis Example 2

2.40 g of polyglycidyl methacrylate (manufactured by Maruzen Petrochemical Co., Ltd.), 2.51 g of 4-vinylbenzoic acid (manufactured by Tosoh Corporation), 0.36 g of dibutyl hydroxy toluene (manufactured by Tokyo Chemical Industry Co., Ltd.), and 0.16 g of tetrabutylphosphonium bromide (manufactured by Hokko Chemical Industry Co., Ltd.) were added to and dissolved in 25 g of propylene glycol monomethyl ether acetate and 25 g of propylene glycol monomethyl ether in a reaction vessel. The reaction vessel was purged with nitrogen, and then the reaction was performed at 80° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer in the prepared polymer solution was subjected to GPC analysis, and found to have a weight-average molecular weight of 18391 in terms of standard polystyrene. The polymer prepared in this Synthesis Example has a structural unit represented by the following Formula (1b):

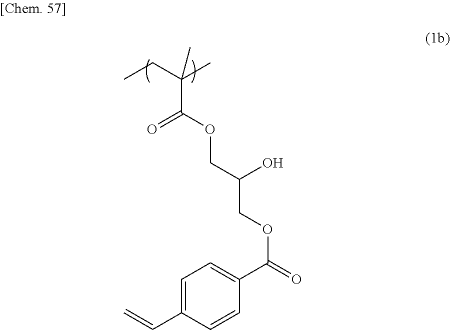

### Synthesis Example 3

3.00 g of polyglycidyl methacrylate (manufactured by Maruzen Petrochemical Co., Ltd.), 2.38 g of propionic acid (manufactured by Tokyo Chemical Industry Co., Ltd.), and 0.21 g of tetrabutylphosphonium bromide (manufactured by Hokko Chemical Industry Co., Ltd.) were added to and dissolved in 32 g of propylene glycol monomethyl ether acetate and 32 g of propylene glycol monomethyl ether in a reaction vessel. The reaction vessel was purged with nitrogen, and then the reaction was performed at 80° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer in the prepared polymer solution was subjected to GPC analysis, and found to have a weight-average molecular weight of 10426 in terms of standard polystyrene. The polymer prepared in this Synthesis Example has a structural unit represented by the following Formula (2a):

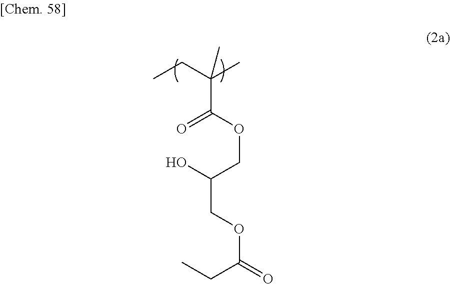

### Synthesis Example 4

3.00 g of polyglycidyl methacrylate (manufactured by Maruzen Petrochemical Co., Ltd.), 2.62 g of benzoic acid (manufactured by Tokyo Chemical Industry Co., Ltd.), and 0.14 g of tetrabutylphosphonium bromide (manufactured by Hokko Chemical Industry Co., Ltd.) were added to and dissolved in 25 g of propylene glycol monomethyl ether acetate and 25 g of propylene glycol monomethyl ether in a reaction vessel. The reaction vessel was purged with nitrogen, and then the reaction was performed at 80° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer in the prepared polymer solution was subjected to GPC analysis, and found to have a weight-average molecular weight of 18124 in terms of standard polystyrene. The polymer prepared in this Synthesis Example has a structural unit represented by the following Formula (2b):

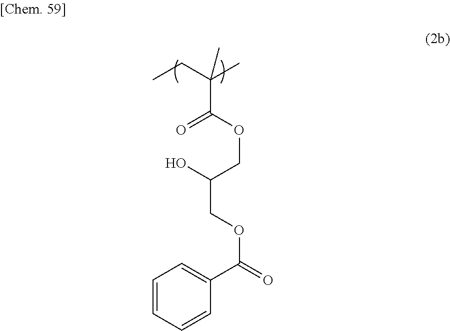

### Synthesis Example 5

6.00 g of polyglycidyl methacrylate (manufactured by Maruzen Petrochemical Co., Ltd.), 4.88 g of sorbic acid (manufactured by Tokyo Chemical Industry Co., Ltd.), 0.02 g of hydroquinone (manufactured by Tokyo Chemical Industry Co., Ltd.), and 0.46 g of tetrabutylphosphonium bromide (manufactured by Hokko Chemical Industry Co., Ltd.) were added to and dissolved in 16.7 g of propylene glycol monomethyl ether acetate and 16.7 g of propylene glycol monomethyl ether in a reaction vessel. The reaction vessel was purged with nitrogen, and then the reaction was performed at 100° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer solution was cooled to room temperature, and then a mixed solvent of propylene glycol monomethyl ether/propylene glycol monomethyl ether acetate was added thereto to prepare a 10 mass % solution. The polymer in the prepared polymer solution was subjected to GPC analysis, and found to have a weight-average molecular weight of 24300 in terms of standard polystyrene. The polymer prepared in this Synthesis Example has a structural unit represented by the following Formula (1c):

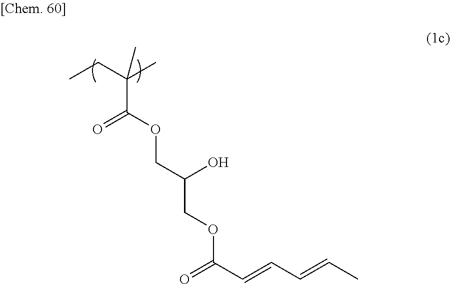

### Synthesis Example 6

6.00 g of polyglycidyl methacrylate (manufactured by Maruzen Petrochemical Co., Ltd.), 3.14 g of acrylic acid (manufactured by Tokyo Chemical Industry Co., Ltd.), 0.02 g of hydroquinone (manufactured by Tokyo Chemical Industry Co., Ltd.), and 0.46 g of tetrabutylphosphonium bromide (manufactured by Hokko Chemical Industry Co., Ltd.) were added to and dissolved in 14.1 g of propylene glycol monomethyl ether acetate and 14.1 g of propylene glycol monomethyl ether in a reaction vessel. The reaction vessel was purged with nitrogen, and then the reaction was performed at 80° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer solution was cooled to room temperature, and then a mixed solvent of propylene glycol monomethyl ether/propylene glycol monomethyl ether acetate was added thereto to prepare a 10 mass % solution. The polymer in the prepared polymer solution was subjected to GPC analysis, and found to have a weight-average molecular weight of 21100 in terms of standard polystyrene. The polymer prepared in this Synthesis Example has a structural unit represented by the following Formula (1d):

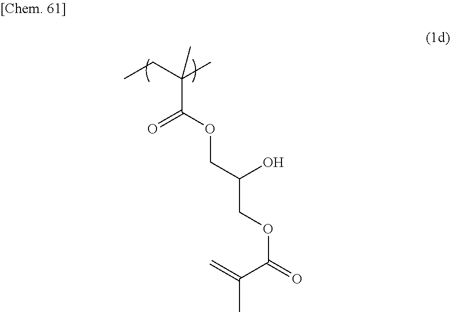

### Synthesis Example 7

6.00 g of polyglycidyl methacrylate (manufactured by Maruzen Petrochemical Co., Ltd.), 3.66 g of tetrolic acid (manufactured by Tokyo Chemical Industry Co., Ltd.), 0.02 g of hydroquinone (manufactured by Tokyo Chemical Industry Co., Ltd.), and 0.46 g of tetrabutylphosphonium bromide (manufactured by Hokko Chemical Industry Co., Ltd.) were added to and dissolved in 14.9 g of propylene glycol monomethyl ether acetate and 14.9 g of propylene glycol monomethyl ether in a reaction vessel. The reaction vessel was purged with nitrogen, and then the reaction was performed at 100° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer solution was cooled to room temperature, and then a mixed solvent of propylene glycol monomethyl ether/propylene glycol monomethyl ether acetate was added thereto to prepare a 10 mass % solution. The polymer in the prepared polymer solution was subjected to GPC analysis, and found to have a weight-average molecular weight of 21000 in terms of standard polystyrene. The polymer prepared in this Synthesis Example has a structural unit represented by the following Formula (1e):

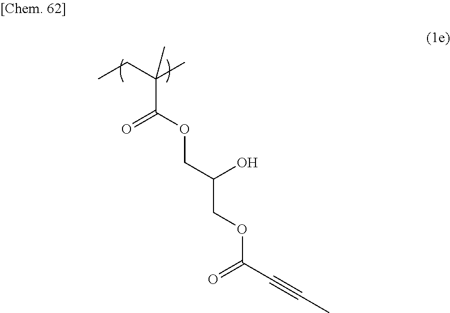

### Synthesis Example 8

6.00 g of polyglycidyl methacrylate, 4.16 g of tiglic acid (manufactured by Tokyo Chemical Industry Co., Ltd.), 0.02 g of hydroquinone (manufactured by Tokyo Chemical Industry Co., Ltd.), and 0.46 g of tetrabutylphosphonium bromide (manufactured by Hokko Chemical Industry Co., Ltd.) were added to and dissolved in 15.7 g of propylene glycol monomethyl ether acetate and 15.7 g of propylene glycol monomethyl ether in a reaction vessel. The reaction vessel was purged with nitrogen, and then the reaction was performed at 100° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer solution was cooled to room temperature, and then a mixed solvent of propylene glycol monomethyl ether/propylene glycol monomethyl ether acetate was added thereto to prepare a 10 mass % solution. The polymer in the prepared polymer solution was subjected to GPC analysis, and found to have a weight-average molecular weight of 5600 in terms of standard polystyrene. The polymer prepared in this Synthesis Example has a structural unit represented by the following Formula (if):

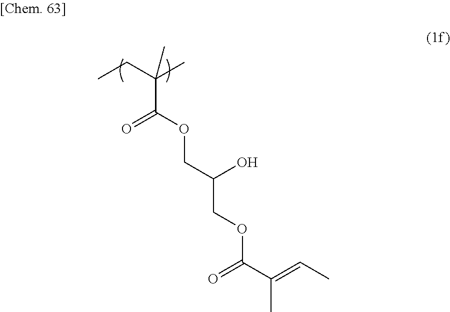

### Synthesis Example 9

6.00 g of polyglycidyl methacrylate, 5.24 g of 1-cyclohexene-1-carboxylic acid (manufactured by Tokyo Chemical Industry Co., Ltd.), 0.02 g of hydroquinone (manufactured by Tokyo Chemical Industry Co., Ltd.), and 0.46 g of tetrabutylphosphonium bromide (manufactured by Hokko Chemical Industry Co., Ltd.) were added to and dissolved in 17.3 g of propylene glycol monomethyl ether acetate and 17.3 g of propylene glycol monomethyl ether in a reaction vessel. The reaction vessel was purged with nitrogen, and then the reaction was performed at 100° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer solution was cooled to room temperature, and then a mixed solvent of propylene glycol monomethyl ether/propylene glycol monomethyl ether acetate was added thereto to prepare a 10 mass % solution. The polymer in the prepared polymer solution was subjected to GPC analysis, and found to have a weight-average molecular weight of 6000 in terms of standard polystyrene. The polymer prepared in this Synthesis Example has a structural unit represented by the following Formula (1g):

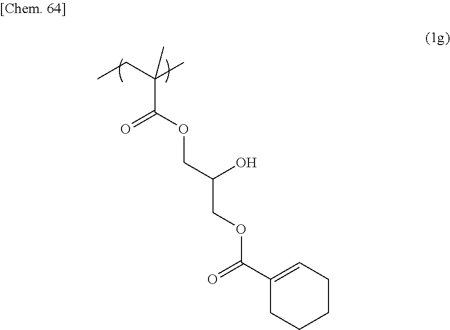

### Synthesis Example 10

6.00 g of polyglycidyl methacrylate, 6.74 g of 2-benzylacrylic acid (manufactured by Tokyo Chemical Industry Co., Ltd.), 0.02 g of hydroquinone (manufactured by Tokyo Chemical Industry Co., Ltd.), and 0.46 g of tetrabutylphosphonium bromide (manufactured by Hokko Chemical Industry Co., Ltd.) were added to and dissolved in 19.6 g of propylene glycol monomethyl ether acetate and 19.6 g of propylene glycol monomethyl ether in a reaction vessel. The reaction vessel was purged with nitrogen, and then the reaction was performed at 100° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer solution was cooled to room temperature, and then a mixed solvent of propylene glycol monomethyl ether/propylene glycol monomethyl ether acetate was added thereto to prepare a 10 mass % solution. The polymer in the prepared polymer solution was subjected to GPC analysis, and found to have a weight-average molecular weight of 6800 in terms of standard polystyrene. The polymer prepared in this Synthesis Example has a structural unit represented by the following Formula (1h):

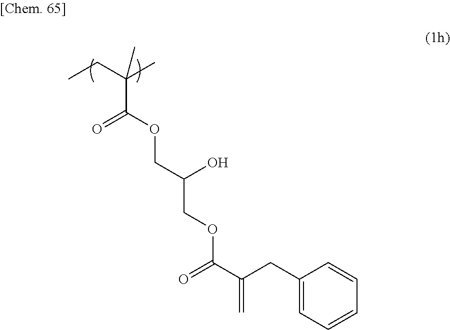

### Synthesis Example 11

6.00 g of polyglycidyl methacrylate, 6.78 g of 5-norbornene-2,3-dicarboximide (manufactured by Tokyo Chemical Industry Co., Ltd.), 0.02 g of hydroquinone (manufactured by Tokyo Chemical Industry Co., Ltd.), and 0.46 g of tetrabutylphosphonium bromide (manufactured by Hokko Chemical Industry Co., Ltd.) were added to and dissolved in 19.6 g of propylene glycol monomethyl ether acetate and 19.6 g of propylene glycol monomethyl ether in a reaction vessel. The reaction vessel was purged with nitrogen, and then the reaction was performed at 100° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer solution was cooled to room temperature, and then a mixed solvent of propylene glycol monomethyl ether/propylene glycol monomethyl ether acetate was added thereto to prepare a 10 mass % solution. The polymer in the prepared polymer solution was subjected to GPC analysis, and found to have a weight-average molecular weight of 4600 in terms of standard polystyrene. The polymer prepared in this Synthesis Example has a structural unit represented by the following Formula (1i):

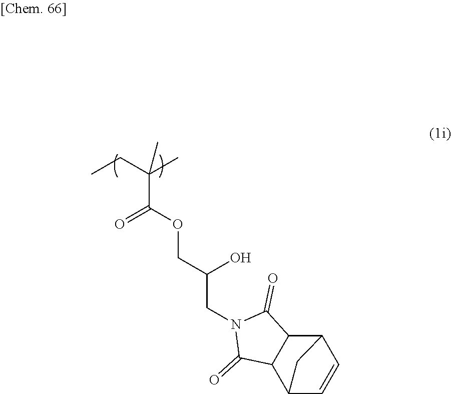

### Synthesis Example 12

6.00 g of polyglycidyl methacrylate, 6.78 g of trans-cinnamic acid (manufactured by Tokyo Chemical Industry Co., Ltd.), 0.02 g of hydroquinone (manufactured by Tokyo Chemical Industry Co., Ltd.), and 0.46 g of tetrabutylphosphonium bromide (manufactured by Hokko Chemical Industry Co., Ltd.) were added to and dissolved in 18.7 g of propylene glycol monomethyl ether acetate and 18.7 g of propylene glycol monomethyl ether in a reaction vessel. The reaction vessel was purged with nitrogen, and then the reaction was performed at 100° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer solution was cooled to room temperature, and then a mixed solvent of propylene glycol monomethyl ether/propylene glycol monomethyl ether acetate was added thereto to prepare a 10 mass % solution. The polymer in the prepared polymer solution was subjected to GPC analysis, and found to have a weight-average molecular weight of 6400 in terms of standard polystyrene. The polymer prepared in this Synthesis Example has a structural unit represented by the following Formula (1j):

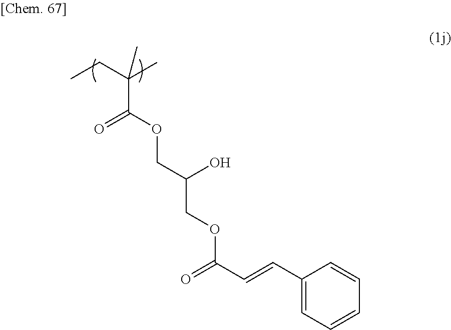

### Synthesis Example 13

6.00 g of polyglycidyl methacrylate, 7.41 g of trans-4-methoxycinnamic acid (manufactured by Tokyo Chemical Industry Co., Ltd.), 0.02 g of hydroquinone (manufactured by Tokyo Chemical Industry Co., Ltd.), and 0.46 g of tetrabutylphosphonium bromide (manufactured by Hokko Chemical Industry Co., Ltd.) were added to and dissolved in 20.6 g of propylene glycol monomethyl ether acetate and 20.6 g of propylene glycol monomethyl ether in a reaction vessel. The reaction vessel was purged with nitrogen, and then the reaction was performed at 100° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer solution was cooled to room temperature, and then a mixed solvent of propylene glycol monomethyl ether/propylene glycol monomethyl ether acetate was added thereto to prepare a 10 mass % solution. The polymer in the prepared polymer solution was subjected to GPC analysis, and found to have a weight-average molecular weight of 6800 in terms of standard polystyrene. The polymer prepared in this Synthesis Example has a structural unit represented by the following Formula (1k):

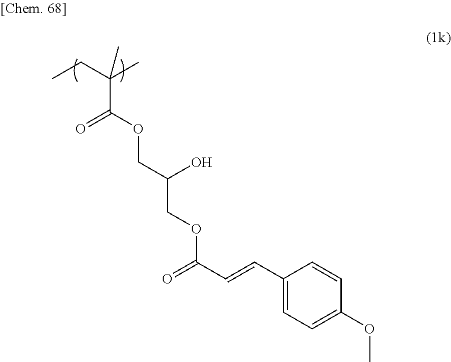

### Synthesis Example 14

6.00 g of polyglycidyl methacrylate, 9.32 g of a-phenylcinnamic acid (manufactured by Tokyo Chemical Industry Co., Ltd.), 0.02 g of hydroquinone (manufactured by Tokyo Chemical Industry Co., Ltd.), and 0.46 g of tetrabutylphosphonium bromide (manufactured by Hokko Chemical Industry Co., Ltd.) were added to and dissolved in 23.4 g of propylene glycol monomethyl ether acetate and 23.4 g of propylene glycol monomethyl ether in a reaction vessel. The reaction vessel was purged with nitrogen, and then the reaction was performed at 100° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer solution was cooled to room temperature, and then a mixed solvent of propylene glycol monomethyl ether/propylene glycol monomethyl ether acetate was added thereto to prepare a 10 mass % solution. The polymer in the prepared polymer solution was subjected to GPC analysis, and found to have a weight-average molecular weight of 6800 in terms of standard polystyrene. The polymer prepared in this Synthesis Example has a structural unit represented by the following Formula (1 1):

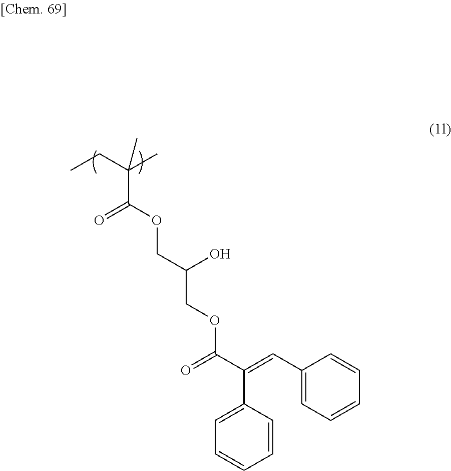

### Synthesis Example 15

6.00 g of polyglycidyl methacrylate, 5.41 g of monomethyl fumarate (manufactured by Tokyo Chemical Industry Co., Ltd.), 0.02 g of hydroquinone (manufactured by Tokyo Chemical Industry Co., Ltd.), and 0.46 g of tetrabutylphosphonium bromide (manufactured by Hokko Chemical Industry Co., Ltd.) were added to and dissolved in 17.6 g of propylene glycol monomethyl ether acetate and 17.6 g of propylene glycol monomethyl ether in a reaction vessel. The reaction vessel was purged with nitrogen, and then the reaction was performed at 100° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer solution was cooled to room temperature, and then a mixed solvent of propylene glycol monomethyl ether/propylene glycol monomethyl ether acetate was added thereto to prepare a 10 mass % solution. The polymer in the prepared polymer solution was subjected to GPC analysis, and found to have a weight-average molecular weight of 7500 in terms of standard polystyrene. The polymer prepared in this Synthesis Example has a structural unit represented by the following Formula (1m):

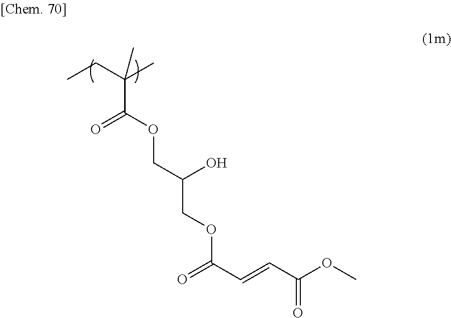

### Synthesis Example 16

4.50 g of a random copolymer of 70 mol % glycidyl methacrylate and 30 mol % 2-hydroxypropyl methacrylate, 2.71 g of sorbic acid (manufactured by Tokyo Chemical Industry Co., Ltd.), 0.01 g of hydroquinone (manufactured by Tokyo Chemical Industry Co., Ltd.), and 0.27 g of tetrabutylphosphonium bromide (manufactured by Hokko Chemical Industry Co., Ltd.) were added to and dissolved in 23.0 g of propylene glycol monomethyl ether in a reaction vessel. The reaction vessel was purged with nitrogen, and then the reaction was performed at 100° C. for 24 hours to prepare a polymer solution. The polymer solution does not become cloudy even when cooled to room temperature, and has good solubility. The polymer solution was cooled to room temperature, and then propylene glycol monomethyl ether was added thereto to prepare a 10 mass % solution. The polymer in the prepared polymer solution was subjected to GPC analysis, and found to have a weight-average molecular weight of 21400 in terms of standard polystyrene. The polymer prepared in this Synthesis Example has structural units represented by the following Formulae (1c) and (2c):

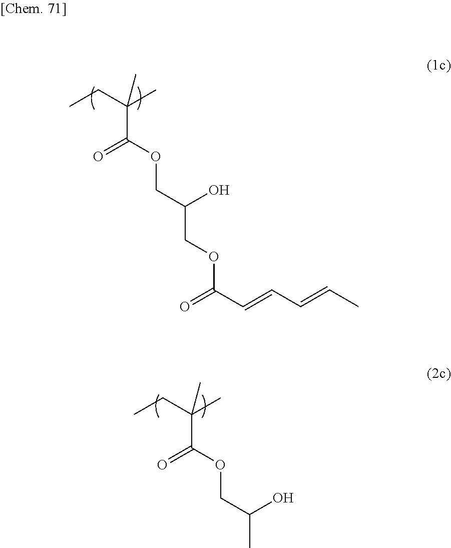

### Synthesis Example 17

5.46 g of a random copolymer of 70 mol % glycidyl methacrylate and 30 mol % hydroxyethyl acrylamide, 3.10 g of sorbic acid (manufactured by Tokyo Chemical Industry Co., Ltd.), 0.01 g of hydroquinone (manufactured by Tokyo Chemical Industry Co., Ltd.), and 0.31 g of tetrabutylphosphonium bromide (manufactured by Hokko Chemical Industry Co., Ltd.) were added to and dissolved in 26.6 g of propylene glycol monomethyl ether in a reaction vessel. The reaction vessel was purged with nitrogen, and then the reaction was performed at 100° C. for 24 hours to prepare a polymer solution. The polymer solution does not become cloudy even when cooled to room temperature, and has good solubility. The polymer solution was cooled to room temperature, and then propylene glycol monomethyl ether was added thereto to prepare a 10 mass % solution. The polymer in the prepared polymer solution was subjected to GPC analysis, and found to have a weight-average molecular weight of 18900 in terms of standard polystyrene. The polymer prepared in this Synthesis Example has structural units represented by the following Formulae (1c) and (2d):

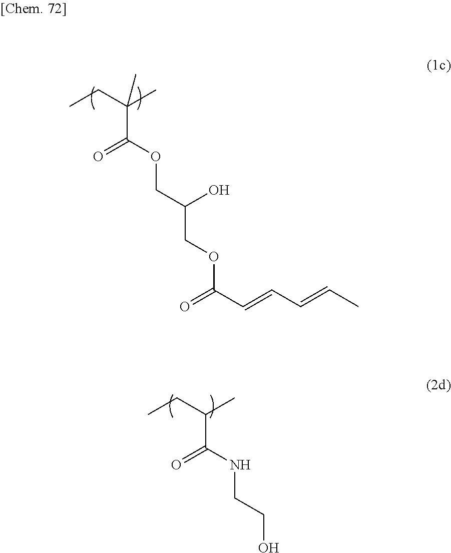

### Synthesis Example 18

6.00 g of polyglycidyl methacrylate (manufactured by Maruzen Petrochemical Co., Ltd.), 2.72 g of methacrylic acid (manufactured by Tokyo Chemical Industry Co., Ltd.), 1.17 g of 2,2-bis(hydroxymethyl)butyric acid (manufactured by Tokyo Chemical Industry Co., Ltd.), 0.02 g of hydroquinone (manufactured by Tokyo Chemical Industry Co., Ltd.), and 1.34 g of tetrabutylphosphonium bromide (manufactured by Hokko Chemical Industry Co., Ltd.) were added to and dissolved in 22.0 g of propylene glycol monomethyl ether acetate and 22.0 g of propylene glycol monomethyl ether in a reaction vessel. The reaction vessel was purged with nitrogen, and then the reaction was performed at 85° C. for 24 hours to prepare a polymer solution. The polymer solution does not become cloudy even when cooled to room temperature, and has good solubility in a mixed solvent of propylene glycol monomethyl ether/propylene glycol monomethyl ether acetate. The polymer solution was cooled to room temperature, and then a mixed solvent of propylene glycol monomethyl ether/propylene glycol monomethyl ether acetate was added thereto to prepare a 10 mass % solution. The polymer in the prepared polymer solution was subjected to GPC analysis, and found to have a weight-average molecular weight of 21900 in terms of standard polystyrene. The polymer prepared in this Synthesis Example has structural units represented by the following Formulae (1a) and (2e):

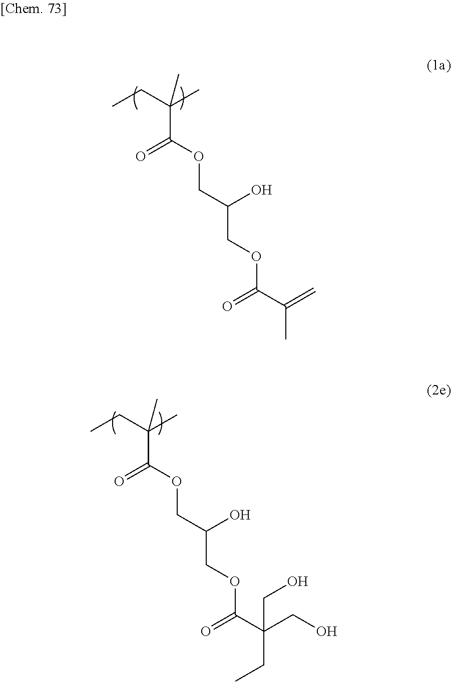

### Synthesis Example 19

7.28 g of a random copolymer of 20 mol % glycidyl methacrylate and 80 mol % tert-butoxystyrene, 2.17 g of methacrylic acid (manufactured by Tokyo Chemical Industry Co., Ltd.), 0.01 g of hydroquinone (manufactured by Tokyo Chemical Industry Co., Ltd.), and 0.49 g of tetrabutylphosphonium bromide (manufactured by Hokko Chemical Industry Co., Ltd.) were added to and dissolved in 39.8 g of propylene glycol monomethyl ether in a reaction vessel. The reaction vessel was purged with nitrogen, and then the reaction was performed at 85° C. for 24 hours to prepare a polymer solution. The polymer solution does not become cloudy even when cooled to room temperature, and has good solubility. The polymer solution was cooled to room temperature, and then propylene glycol monomethyl ether was added thereto to prepare a 10 mass % solution. The polymer in the prepared polymer solution was subjected to GPC analysis, and found to have a weight-average molecular weight of 11400 in terms of standard polystyrene. The polymer prepared in this Synthesis Example has structural units represented by the following Formulae (1a) and (2f):

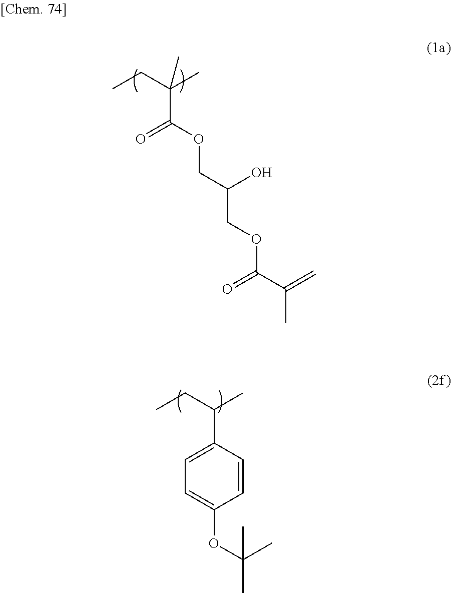

### Synthesis Example 20

5.36 g of a random copolymer of 35 mol % glycidyl methacrylate and 65 mol % 2-hydroxypropyl methacrylate, 1.97 g of a-cyanocinnamic acid (manufactured by Tokyo Chemical Industry Co., Ltd.), 0.01 g of hydroquinone (manufactured by Tokyo Chemical Industry Co., Ltd.), and 0.15 g of tetrabutylphosphonium bromide (manufactured by Hokko Chemical Industry Co., Ltd.) were added to and dissolved in 29.7 g of propylene glycol monomethyl ether in a reaction vessel. The reaction vessel was purged with nitrogen, and then the reaction was performed under reflux for 24 hours to prepare a polymer solution. The polymer solution does not become cloudy even when cooled to room temperature, and has good solubility. The polymer solution was cooled to room temperature, and then propylene glycol monomethyl ether was added thereto to prepare a 10 mass % solution. The polymer in the prepared polymer solution was subjected to GPC analysis, and found to have a weight-average molecular weight of 5600 in terms of standard polystyrene. The polymer prepared in this Synthesis Example has structural units represented by the following Formulae (in) and (2c):

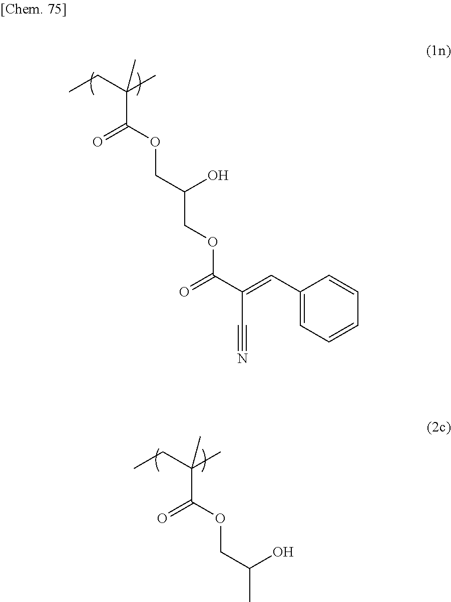

### Synthesis Example 21

5.13 g of a random copolymer of 35 mol % glycidyl methacrylate and 65 mol % 2-hydroxypropyl methacrylate, 2.20 g of 4-nitrocinnamic acid (manufactured by Tokyo Chemical Industry Co., Ltd.), 0.01 g of hydroquinone (manufactured by Tokyo Chemical Industry Co., Ltd.), and 0.15 g of tetrabutylphosphonium bromide (manufactured by Hokko Chemical Industry Co., Ltd.) were added to and dissolved in 30.0 g of propylene glycol monomethyl ether in a reaction vessel. The reaction vessel was purged with nitrogen, and then the reaction was performed under reflux for 24 hours to prepare a polymer solution. The polymer solution does not become cloudy even when cooled to room temperature, and has good solubility. The polymer solution was cooled to room temperature, and then propylene glycol monomethyl ether was added thereto to prepare a 10 mass % solution. The polymer in the prepared polymer solution was subjected to GPC analysis, and found to have a weight-average molecular weight of 8800 in terms of standard polystyrene. The polymer prepared in this Synthesis Example has structural units represented by the following Formulae (10) and (2c):

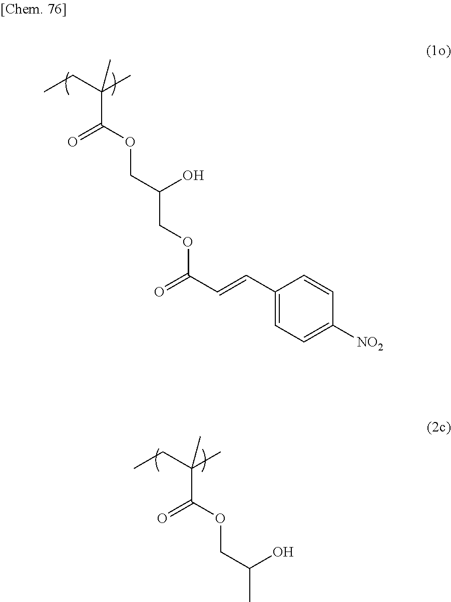

### Synthesis Example 22

5.13 g of a random copolymer of 35 mol % glycidyl methacrylate and 65 mol % 2-hydroxypropyl methacrylate, 2.20 g of 3-nitrocinnamic acid (manufactured by Tokyo Chemical Industry Co., Ltd.), 0.01 g of hydroquinone (manufactured by Tokyo Chemical Industry Co., Ltd.), and 0.15 g of tetrabutylphosphonium bromide (manufactured by Hokko Chemical Industry Co., Ltd.) were added to and dissolved in 30.0 g of propylene glycol monomethyl ether in a reaction vessel. The reaction vessel was purged with nitrogen, and then the reaction was performed under reflux for 24 hours to prepare a polymer solution. The polymer solution does not become cloudy even when cooled to room temperature, and has good solubility. The polymer solution was cooled to room temperature, and then propylene glycol monomethyl ether was added thereto to prepare a 10 mass % solution. The polymer in the prepared polymer solution was subjected to GPC analysis, and found to have a weight-average molecular weight of 7700 in terms of standard polystyrene. The polymer prepared in this Synthesis Example has structural units represented by the following Formulae (1p) and (2c):

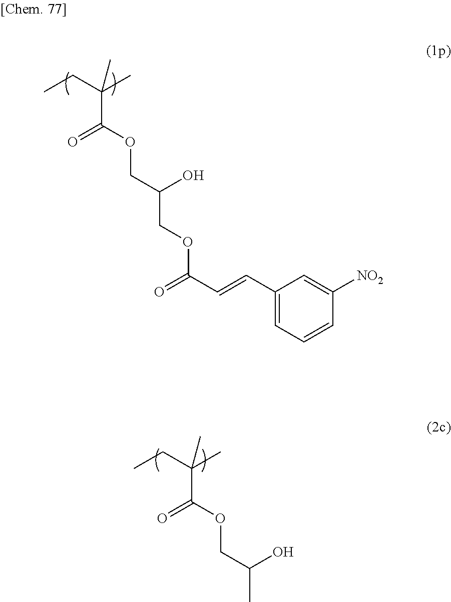

### Synthesis Example 23

3.94 g of a random copolymer of 50 mol % glycidyl methacrylate, 30 mol % 2-hydroxypropyl methacrylate, and 20 mol % 1-adamantyl methacrylate, 2.34 g of 4-nitrocinnamic acid (manufactured by Tokyo Chemical Industry Co., Ltd.), 0.01 g of hydroquinone (manufactured by Tokyo Chemical Industry Co., Ltd.), and 0.15 g of tetrabutylphosphonium bromide (manufactured by Hokko Chemical Industry Co., Ltd.) were added to and dissolved in 25.6 g of propylene glycol monomethyl ether in a reaction vessel. The reaction vessel was purged with nitrogen, and then the reaction was performed under reflux for 24 hours to prepare a polymer solution. The polymer solution does not become cloudy even when cooled to room temperature, and has good solubility. The polymer solution was cooled to room temperature, and then propylene glycol monomethyl ether was added thereto to prepare a 10 mass % solution. The polymer in the prepared polymer solution was subjected to GPC analysis, and found to have a weight-average molecular weight of 17400 in terms of standard polystyrene. The polymer prepared in this Synthesis Example has structural units represented by the following Formulae (1o), (2c), and (2g):

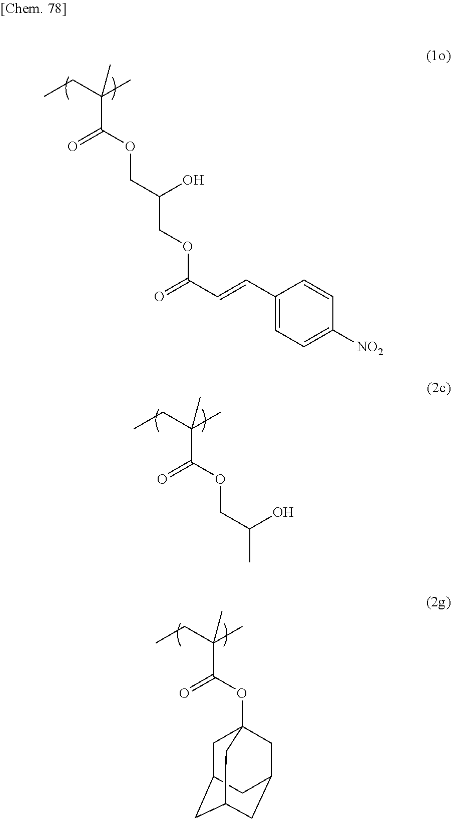

### Example 1

To 1.4 g of the polymer solution (solid content: 7.91 mass %) prepared in Synthesis Example 1, 33.6 g of propylene glycol monomethyl ether and 15 g of propylene glycol monomethyl ether acetate were added for dilution. Thereafter, the mixture was filtered using a polyethylene microfilter having a pore size of 0.05 μm to form a resist underlayer film-forming composition for lithography.

### Example 2

To 1.4 g of the polymer solution (solid content: 7.68 mass %) prepared in Synthesis Example 2, 34 g of propylene glycol monomethyl ether and 15 g of propylene glycol monomethyl ether acetate were added for dilution. Thereafter, the mixture was filtered using a polyethylene microfilter having a pore size of 0.05 μm to form a resist underlayer film-forming composition for lithography.

### Example 3

To 1.4 g of the polymer solution (solid content: 7.91 mass %) prepared in Synthesis Example 1, 0.43 g of a 5 mass % propylene glycol monomethyl ether solution of tetramethoxymethyl glycoluril (manufactured by Nihon Cytec Industries Inc.), 0.22 g of a 1 mass % propylene glycol monomethyl ether solution of pyridinium phenolsulfonic acid, 33 g of propylene glycol monomethyl ether, and 15 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 4

To 1.4 g of the polymer solution (solid content: 7.68 mass %) prepared in Synthesis Example 2, 0.43 g of a 5 mass % propylene glycol monomethyl ether solution of tetramethoxymethyl glycoluril (manufactured by Nihon Cytec Industries Inc.), 0.22 g of a 1 mass % propylene glycol monomethyl ether solution of pyridinium phenolsulfonic acid, 33 g of propylene glycol monomethyl ether, and 15 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 5

To 1.54 g of the polymer solution (solid content: 10 mass %) prepared in Synthesis Example 5, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 6

To 1.54 g of the polymer solution (solid content: 10 mass %) prepared in Synthesis Example 6, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 7

To 1.54 g of the polymer solution (solid content: 10 mass %) prepared in Synthesis Example 7, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 8

To 1.54 g of the polymer solution (solid content: 10 mass %) prepared in Synthesis Example 8, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 9

To 1.54 g of the polymer solution (solid content: 10 mass %) prepared in Synthesis Example 9, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 10

To 1.54 g of the polymer solution (solid content: 10 mass %) prepared in Synthesis Example 10, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 11

To 1.54 g of the polymer solution (solid content: 10 mass %) prepared in Synthesis Example 11, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 12

To 1.54 g of the polymer solution (solid content: 10 mass %) prepared in Synthesis Example 12, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 13

To 1.54 g of the polymer solution (solid content: 10 mass %) prepared in Synthesis Example 13, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 14

To 1.54 g of the polymer solution (solid content: 10 mass %) prepared in Synthesis Example 14, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 15

To 1.54 g of the polymer solution (solid content: 10 mass %) prepared in Synthesis Example 15, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 16

To 1.54 g of the polymer solution (solid content: 10 mass %) prepared in Synthesis Example 16, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 17

To 1.54 g of the polymer solution (solid content: 10 mass %) prepared in Synthesis Example 17, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 18

To 1.54 g of the polymer solution (solid content: 10 mass %) prepared in Synthesis Example 18, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 19

To 1.54 g of the polymer solution (solid content: 10 mass %) prepared in Synthesis Example 19, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 20

To 1.54 g of the polymer solution (solid content: 10 mass %) prepared in Synthesis Example 20, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 21

To 1.54 g of the polymer solution (solid content: 10 mass %) prepared in Synthesis Example 21, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 22

To 1.54 g of the polymer solution (solid content: 10 mass %) prepared in Synthesis Example 22, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Example 23

To 1.54 g of the polymer solution (solid content: 10 mass %) prepared in Synthesis Example 23, 0.85 g of a 5 mass % propylene glycol monomethyl ether solution of tetramethoxymethyl glycoluril (manufactured by Nihon Cytec Industries Inc.), 0.38 g of a 1 mass % propylene glycol monomethyl ether solution of pyridinium phenolsulfonic acid, 87.9 g of propylene glycol monomethyl ether, and 9.3 g of propylene glycol monomethyl ether acetate were added and dissolved. Thereafter, the mixture was filtered using a polyethylene microfilter having a pore size of 0.05 μm to form a resist underlayer film-forming composition for lithography.

### Comparative Example 1

To 0.41 g of the polymer solution (solid content: 18.45 mass %) prepared in Synthesis Example 3, 0.38 g of a 5 mass % propylene glycol monomethyl ether solution of tetramethoxymethyl glycoluril (manufactured by Nihon Cytec Industries Inc.), 0.19 g of a 1 mass % propylene glycol monomethyl ether solution of pyridinium phenolsulfonic acid, 33 g of propylene glycol monomethyl ether, and 15 g of propylene glycol monomethyl ether acetate were added and dissolved. Thereafter, the mixture was filtered using a polyethylene microfilter having a pore size of 0.05 μm to form a resist underlayer film-forming composition for lithography.

### Comparative Example 2

To 0.21 g of the polymer solution (solid content: 40.20 mass %) prepared in Synthesis Example 4, 0.40 g of a 5 mass % propylene glycol monomethyl ether solution of tetramethoxymethyl glycoluril (manufactured by Nihon Cytec Industries Inc.), 0.22 g of a 1 mass % propylene glycol monomethyl ether solution of pyridinium phenolsulfonic acid, 33 g of propylene glycol monomethyl ether, and 15 g of propylene glycol monomethyl ether acetate were added and dissolved. Thereafter, the mixture was filtered using a polyethylene microfilter having a pore size of 0.05 μm to form a resist underlayer film-forming composition for lithography.

### [Elution Test of Photoresist Solvent]

The resist underlayer film-forming compositions of Examples 1 to 23 and Comparative Examples 1 and 2 were applied onto silicon wafers as semiconductor substrates with a spinner. Each of the silicon wafers was disposed on a hot plate and baked at 215° C. for 1 minute to form resist underlayer films (film thickness: 5 nm). These resist underlayer films were immersed in a mixed solvent of propylene glycol monomethyl ether/propylene glycol monomethyl ether acetate at a mass ratio=7/3, i.e. a solvent used for the photoresist, and were confirmed to be insoluble in the solvent.

### [Formation of Positive Resist Pattern by Electron Beam Lithography System]

The resist underlayer film-forming compositions of Examples 1 to 23 and Comparative Examples 1 and 2 were applied onto silicon wafers using a spinner. The silicon wafers were baked on a hot plate at 215° C. for 60 seconds to form resist underlayer films having a film thickness of 5 nm. An EUV positive resist solution (containing a methacrylic polymer) was spin-coated on each of the resist underlayer films, and heated at 110° C. for 60 seconds to form EUV resist films. The resist films were exposed under the predetermined conditions using an electron beam lithography system (ELS-G130). After the exposure, the films were baked (PEB) at 90° C. for 60 seconds, cooled on a cooling plate to room temperature, and developed with an alkaline developer (2.38% TMAH). Thereafter, a line-and-space pattern with a CD size of 22 nm and a pitch of 44 nm was formed. A scanning electron microscope (CG4100 manufactured by Hitachi High-Technologies Corporation) was used to measure the length of the resist pattern. When the CD size was 22 nm, a line pattern without falling or peeling could be formed in Examples 1 to 4 and Comparative Examples 1 to 2.

In the formation of the resist pattern, the exposure amount was increased, and a line pattern having a CD size of 19 nm was formed. A case where a line pattern without falling or peeling could be formed was evaluated as “good”, and a case where falling or peeling of the line pattern was observed was evaluated as “poor”. The evaluation results are shown in Table 1.

TABLE 1

| | Line pattern having CD size of 19 nm |
|---|---|
| Example 1 | Good |
| Example 2 | Good |
| Example 3 | Good |
| Example 4 | Good |
| Example 5 | Good |
| Example 6 | Good |
| Example 7 | Good |
| Example 8 | Good |
| Example 9 | Good |
| Example 10 | Good |
| Example 11 | Good |
| Example 12 | Good |
| Example 13 | Good |
| Example 14 | Good |
| Example 15 | Good |
| Example 16 | Good |
| Example 17 | Good |
| Example 18 | Good |
| Example 19 | Good |
| Example 20 | Good |
| Example 21 | Good |
| Example 22 | Good |
| Example 23 | Good |
| Comparative Example 1 | Poor |
| Comparative Example 2 | Poor |

1. A resist underlayer film-forming composition comprising: a polymer (A); and a solvent, wherein the polymer (A) has, in a side chain, one or two or more polymerizable multiple bonds selected from the group consisting of a carbon-carbon double bond, a carbon-carbon triple bond, a carbon-nitrogen double bond, and a carbon-nitrogen triple bond.

2. The resist underlayer film-forming composition according to claim 1, wherein in the polymer (A), the polymerizable multiple bond is bonded to a main chain of the polymer (A) via a linking group having a structure formed by reacting an epoxy group with a nucleophilic functional group.

3. The resist underlayer film-forming composition according to claim 2, wherein the nucleophilic functional group is one or two or more selected from the group consisting of a carboxy group, a hydroxy group, an amino group, and a thiol group.

4. The resist underlayer film-forming composition according to claim 1,
wherein in the polymer (A), the polymerizable multiple bond is bonded to a main chain of the polymer (A) via a linking group having a structure formed by reacting an isocyanate group with a nucleophilic functional group, and
the nucleophilic functional group is one or two or more selected from the group consisting of a hydroxy group, an amino group, and a thiol group.

5. The resist underlayer film-forming composition according to claim 1, wherein the polymer (A) has a structural unit represented by the following Formula (1): 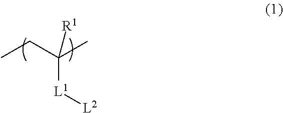
where in Formula (1), R¹ represents a hydrogen atom or an alkyl group having 1 to 10 carbon atoms, L represents a single bond or a linking group, and L² represents a monovalent group having the polymerizable multiple bond.

6. The resist underlayer film-forming composition according to claim 5, wherein L¹-L² in the structural unit represented by Formula (1) has a structure represented by the following Formula (1a), (1b) or (1c): 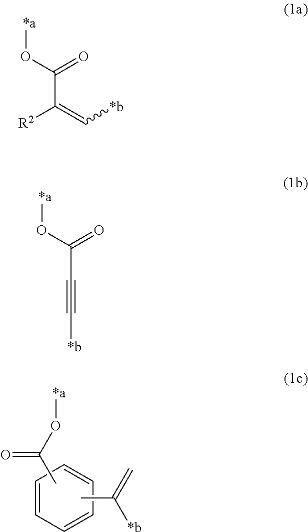
where in Formulae (1a) to (1c), R² represents a hydrogen atom or an alkyl group having 1 to 10 carbon atoms, *a and *b each represent a bonding hand, *a is a main chain side of the polymer (A), and *b is an end side of a side chain of the polymer (A).

7. The resist underlayer film-forming composition according to claim 1, further comprising a crosslinking agent.

8. A resist underlayer film which is a cured product of the resist underlayer film-forming composition according to claim 1.

9. A laminate comprising:
a semiconductor substrate; and
the resist underlayer film according to claim 8.

10. A method for producing a semiconductor element, the method comprising the steps of:
forming a resist underlayer film on a semiconductor substrate using the resist underlayer film-forming composition according to claim 1; and
forming a resist film on the resist underlayer film.

11. A method for forming a pattern, the method comprising the steps of:
forming a resist underlayer film on a semiconductor substrate using the resist underlayer film-forming composition according to claim 1;
forming a resist film on the resist underlayer film;
irradiating the resist film with light or an electron beam, and then developing the resist film to form a resist pattern; and
etching the resist underlayer film using the resist pattern as a mask.
